(19) United States
(12) Patent Application Publication
(10) Pub. No.: US 2018/0138357 A1
(43) Pub. Date: May 17, 2018

(54) MICRO-LIGHT EMITTING DIODE (LED) FABRICATION BY LAYER TRANSFER

(71) Applicant: QMAT, Inc., Santa Clara, CA (US)

(72) Inventor: Francois J. HENLEY, Saratoga, CA (US)

(21) Appl. No.: 15/809,023

(22) Filed: Nov. 10, 2017

Related U.S. Application Data
(60) Provisional application No. 62/421,149, filed on Nov. 11, 2016.
(60) Provisional application No. 62/433,189, filed on Dec. 12, 2016.

(51) Int. Cl. H01L 33/00; H01L 25/075; H01L 33/06; H01L 33/18; H01L 33/32; H01L 33/50

(52) U.S. Cl. CPC H01L 33/0079; H01L 25/0753; H01L 33/06; H01L 33/18; H01L 2933/0041; H01L 33/502; H01L 33/007; H01L 33/0075; H01L 33/0095; H01L 33/32

(57) ABSTRACT

Embodiments relate to fabricating a micro-Light Emitting Diode (LED) structure utilizing layer-transferred material. In particular, high quality Gallium Nitride (GaN) is grown upon a donor substrate, utilizing techniques such as Hydride Vapor Phase Epitaxy (HVPE). Exemplary donor substrates can comprise GaN, AlN, SiC, sapphire, and/or single crystal silicon—e.g., (111). The large relative thickness (e.g., ˜10's of μm) of GaN grown in this manner, significantly reduces (e.g., to about 2-3×10⁶ cm⁻²) Threading Dislocation Densities (TDDs) present in the material. This allows the cleaved grown GaN material to be well-suited for transfer and incorporation into a micro-LED structure operating at high brightness under low current/heat generation conditions.

### CROSS-REFERENCE TO RELATED APPLICATIONS

The instant United States nonprovisional patent application claims priority to U.S. Provisional Patent Application No. 62/421,149 filed Nov. 11, 2016, as well as to U.S. Provisional Patent Application No. 62/433,189 filed Dec. 12, 2016, both of which are incorporated by reference in their entireties herein for all purposes.

### BACKGROUND

Semiconducting materials find many uses, for example in the formation of logic devices, solar cells, and increasingly, illumination such as general lighting or displays. One type of semiconductor device that can be used for displays is the micro-light emitting diode (micro-LED). In contrast with traditional display technologies such as Liquid-Crystal Display (LCDs) and emissive displays such as Organic LED (OLED) displays, micro-LED's offer significant advantages in terms of reduced power consumption, brightness, and reliability.

### SUMMARY

Embodiments relate to fabricating a micro-Light Emitting Diode (LED) structure utilizing layer-transferred material. In particular, high quality Gallium Nitride (GaN) is grown upon a donor substrate, utilizing techniques such as Hydride Vapor Phase Epitaxy (HVPE) or Liquid-Phase Epitaxy (LPE). Exemplary donor substrates can comprise GaN, AlN, SiC, sapphire, and/or single crystal silicon—e.g., (111). The large relative thickness (e.g., ˜ten to hundreds of μm) of the GaN grown in this manner, significantly reduces (e.g., to about 2-3×10⁶ cm⁻²) Threading Dislocation Densities (TDDs) present in the material. This allows the cleaved grown GaN material to be well-suited for transfer and incorporation into a micro-LED structure that can efficiently operate over a variety of current density regimes.

### BRIEF DESCRIPTION OF THE DRAWINGS

FIG. 1 shows the donor process sequence, layer-transfer process sequence, and micro-LED process sequence forming the main process flow according to certain embodiments.

FIG. 1A shows polar and non-polar forms of GaN.

FIG. 1B shows Ga and N faces of polar GaN.

FIGS. 1C-D show a simplified view of the growth of high quality material over a donor workpiece according to an embodiment.

FIG. 2 shows a view of a process of N-Face donor preparation according to an embodiment.

FIG. 3 plots dislocation density versus thickness of GaN material grown on sapphire.

FIG. 4 plots dislocation density versus thickness of GaN material grown on SiC.

FIGS. 5A-E shows cross-sectional views of a transferred high quality grown material using a 2-step layer-transfer process sequence onto a target substrate for later use in fabricating a micro-LED display.

FIGS. 6A-C show cross-sectional views of a transferred high quality grown material using a 1-step layer-transfer process sequence onto a target substrate for later use in fabricating a micro-LED display.

FIGS. 7A-D show various views of a micro-LED device fabrication sequence.

FIGS. 8A-B show various permanent target substrate configurations.

FIG. 9 shows an embodiment of a manufacturing process flow using a releasable target substrate configuration.

FIG. 10 shows final steps in mounting the micro-LED devices onto a direct-view display backplane.

FIGS. 11A-C shows a manufacturing process allowing normalization of the display input/output function for a collection of pixels.

FIG. 12 plots output power temperature dependence versus current density for a variety of different LED type structures.

FIG. 13 shows the GaN stress in MPa present on a GaN film transferred at room-temperature and subsequently grown at 1050° C. on Quartz substrates.

FIG. 14 shows the GaN stress in MPa present on a GaN film transferred at room-temperature and subsequently grown at 1050° C. on Sapphire substrates.

FIGS. 15A-G show simplified cross-sectional views of an embodiment of a process flow utilizing a protective layer.

### DETAILED DESCRIPTION

Micro-LED structures may exhibit one or more opto-electrical properties. One is the ability of an optically active quantum well region having an area of between about 1 μm×1 μm to 100 μm×100 μm, to support a current density of between about 0.001 A/cm² to 30-35 A/cm².

An optoelectronic device such as a micro-LED may rely upon materials exhibiting semiconductor properties, including but limited to type III/V materials such as gallium nitride (GaN) that is available in various degrees of crystalline order. However, these materials are often difficult to manufacture, especially at high quality levels.

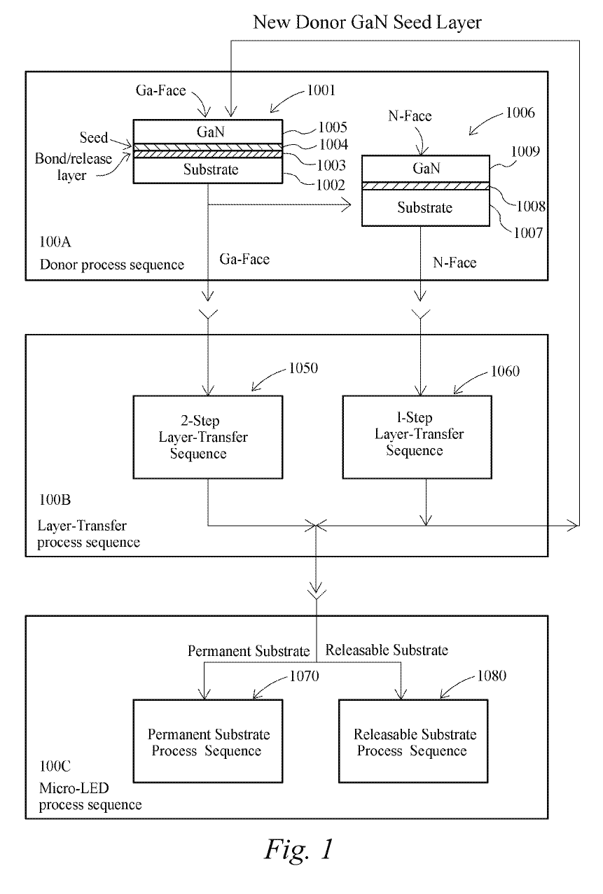

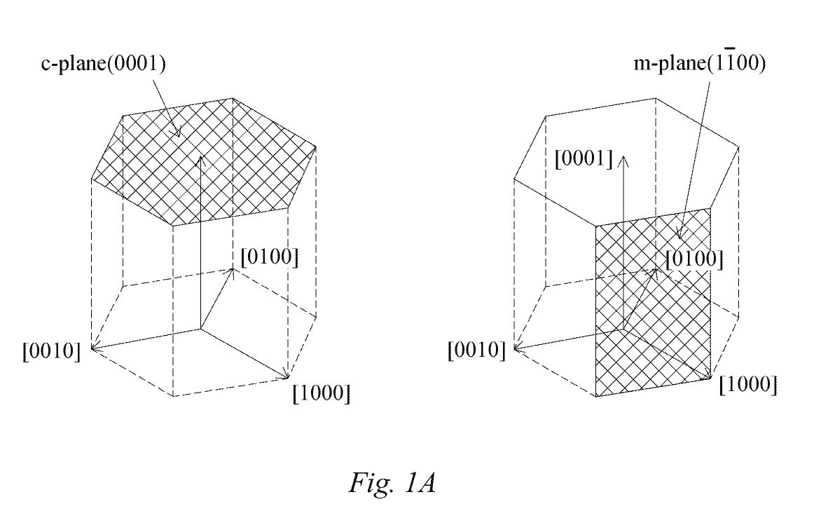

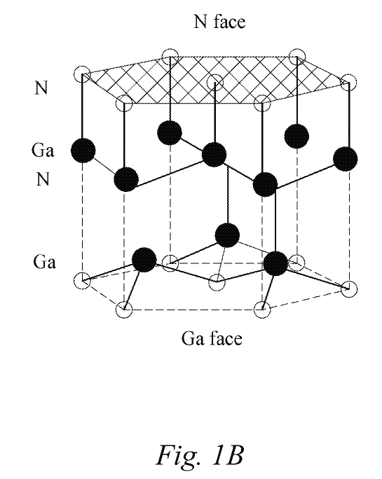

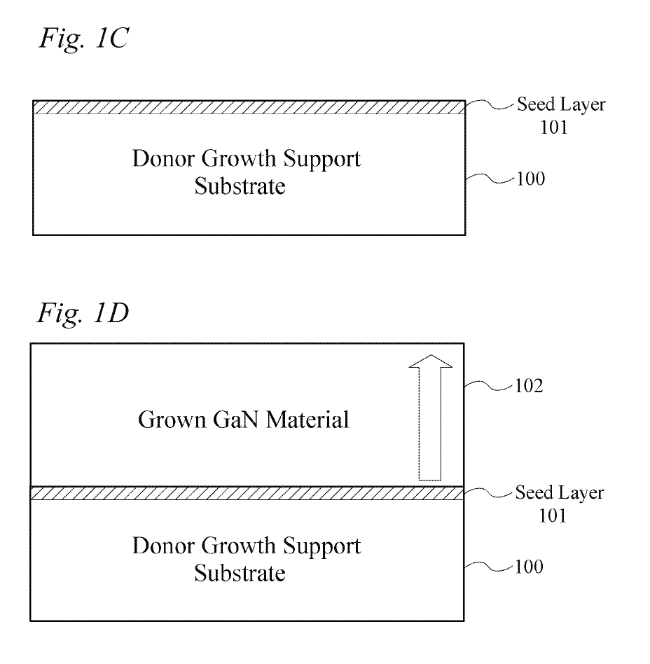

Three major process sequences may define elements according to various embodiments. These are summarized in FIG. 1. The first process sequence 100A is the development of the donor using GaN as the example III-V opto-electronic material. Once the source of the GaN material has been made with the requisite orientation and size, a compatible GaN layer-transfer process sequence 100B is selected to process the donor substrate and transfer a high-quality film of GaN to a MOCVD compatible process substrate. This process substrate can be a temporary substrate that allows release of singulatable micro-LED devices for further processing and mounting on a display or is a permanent substrate that becomes part of the micro-LED display assembly. Reference number 100C shows the micro-LED process sequence options and possible integration of other layers such as phosphor down-conversion and light reflection/scattering layers.

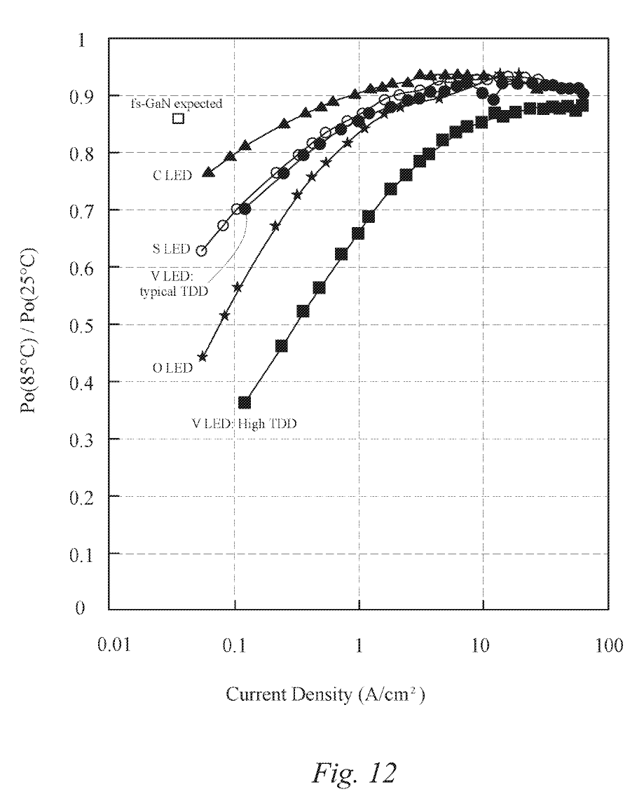

The potential benefits of large-area, cost-effective and high-quality GaN growth layers for micro-LED manufacturing made possible by this invention are numerous. One possible benefit is higher external quantum efficiency (EQE), higher temperature stability and higher yield expected from small area micro-LED devices made with low threading dislocation density (TDD) GaN. FIG. 12 shows a higher temperature stability correlated to lower TDD levels of the GaN in the lower current density (0.01-10 A/cm²) regime of most micro-LED applications. This is in contrast to general lighting devices that are typically operated at 30-100 A/cm² or even higher. At these higher current injection levels, the efficiency (EQE) of general lighting LEDs made from high-TDD GaN material such as GaN-sapphire peak. This is due to a lower relative contribution of non-radiative processes that recombine carriers without emitting photons. At lower injection levels, however, non-radiative recombination processes may become increasingly important. Lower TDD (higher-quality) GaN will have advantages in higher EQE and micro-LED device to device EQE uniformity and stability under differing operating conditions. A 10 μm×10 μm micro-LED device made with current GaN-sapphire growth technologies of about 1×10⁸ cm⁻² TDD levels will have ˜100 defects/micro-LED area while the same micro-LED device made from methods according to this invention of about 1×10⁶ cm⁻² TDD level will have ˜1 defects/micro-LED area.

The large substrate size templates made possible by various embodiments may also permit cost-effective manufacturing of high-quality micro-LED devices compatible with high-volume manufacturing of projection and direct view displays of a large variety of sizes.

Donor Process Sequence

Returning to the donor process sequence 100A of FIG. 1, various types of GaN may be employed as the donor substrate to form the template for growth of the additional material. For example, wurtzite GaN-based materials exists in both polar and non-polar forms. FIG. 1A shows non-polar GaN exhibiting an m-plane (1100). GaN in its non-polar form is relatively expensive. As also shown in FIG. 1C, polar GaN exhibits a c-plane (0001). FIG. 1B shows that polar GaN is characterized by having an N face and a Ga face.

Certain embodiments may feature the Ga face of the donor substrate exposed to growth conditions resulting in the formation of additional GaN also having its Ga face exposed. This is because the Ga face has traditionally proven more amenable to the growth of high quality GaN than the N face.

It is emphasized, however, that other embodiments are possible. For example some applications (e.g., power electronics) may call for growth of GaN material from the N face, rather than from the Ga face. Incorporated by reference herein for all purposes are the following articles: Xun Li et al., “Properties of GaN layers grown on N-face free-standing GaN substrates”, Journal of Crystal Growth 413, 81-85 (2015); A. R. A. Zauner et al., “Homo-epitaxial growth on the N-face of GaN single crystals: the influence of the misorientation on the surface morphology”, Journal of Crystal Growth 240, 14-21 (2002). Accordingly, a donor substrate could feature a GaN layer having an N face exposed for the growth of additional material, rather than a Ga face. Moreover, as described in detail below, processes involving a single layer transfer step from a N face donor would result in the Ga face being exposed and then available for additional GaN growth under beneficial conditions. Because of the relative ease and generally higher experience and quality of MOCVD processes on c-plane Ga-face GaN material, many of the micro-LED device embodiments will be described as made on this particular orientation and face but this invention is not to be viewed as restricted to this choice of GaN or even restricted to GaN in particular. Other crystal orientation and even other III/V materials such as GaP, GaAs and InGaP crystals could be used as micro-LED emission sources. Examples of non down-conversion (non-phosphor) LED configurations using alternative III-V materials will be described in more detail below.

According to an embodiment, the GaN donor process sequence is used to synthesize two classes of c-plane donor substrates that can act as a source of high-quality GaN films compatible with subsequent micro-LED processes. The first is a donor substrate having a Ga-face while the other is a donor substrate having an N-face.

One fabrication approach is illustrated in FIGS. 1C-D. There, a donor workpiece 100 is provided. This donor growth support substrate comprises a material having properties (e.g., lattice constant, coefficient of thermal expansion) compatible with the growth of overlying high quality GaN material. The donor workpiece 100 can have an epitaxial growth seed layer 101 grown or bonded onto it. Examples of seed layer 101 can include but are not limited to bulk GaN, sapphire layers, AlN, SiC, and single crystal silicon—e.g., (111). Incorporated by reference in their entireties herein for all purposes, are the following provisional patent applications describing growth of GaN over various underlying materials: U.S. Provisional Patent Appl. 62/370,169 filed Aug. 2, 2016, and U.S. Provisional Patent Appl. 62/378,126 filed Aug. 22, 2016.

According to certain embodiments the donor growth support substrate material may be selected to have Coefficient of Thermal Expansion (CTE) properties that are compatible with GaN material. Particular examples of possible candidates for substrate materials include AlN, Mullite and others. An example table is given below.

| MATERIAL | CTE |
|---|---|
| GaN | 5.5 × 10⁻⁶ K⁻¹ |
| Polycrystal AlN | 5.4 × 10⁻⁶ K⁻¹ |
| Mullite (3Al₂O₃•2SiO₂) | 5.4 × 10⁻⁶ K⁻¹ |

As shown in FIG. 1D, processing the exposed surface of the seed layer atop of the donor substrate may allow for the formation of additional thickness 102 of high quality GaN material. That additional thickness of GaN material (with or without the accompanying substrate and/or dielectric material) may ultimately be incorporated into a larger optoelectronic device structure (such as a micro-LED).

The general method to calculate the critical thickness h_{c} of GaN grown on a base substrate with a net differential CTE mismatch utilizes critical energy release rate to delaminate thin-films by buckling. Such methods are explained by Hutchinson and Suo in “Mixed Mode Cracking in Layered Materials”, Advances in Applied Mechanics, Vol. 29, pp. 63-187 (1992), which is incorporated by reference in its entirety herein for all purposes.

Using the thermal mismatch generated film stress as the driving energy (σ=E Δα ΔT, where E=Young's Modulus, Δα=CTE mismatch and ΔT=temperature differential), the equation linking this driving energy to the critical thickness characterizing the onset of film cracking/delamination is:

G=0.5(1−υ²)σ²h/E (1)

Where G is the energy release rate, a is the thermal mismatch generated film stress, h is the film thickness and E is Young's modulus.

At the onset of buckling, the energy release rate will equal or exceed the critical energy release rate for the GaN film. This critical energy Go is about 2 J/m². Equation (1) can be rewritten for this condition to solve for the critical thickness h_{c} as:

h_{c}=2E G_{c}/((1−υ²)σ²) (2)

Using E=300 GPa for GaN, v=0.38 for the material parameters and ΔT=1000° C. as the temperature differential between growth and room temperature, a 0.2 ppm/° C. (Δα) CTE mismatch will generate a 60 MPa film stress and allow up to approximately 380 μm GaN thickness on a polycrystal AlN substrate without cracking. This is a sufficiently thick GaN film to be considered as a practical donor seed substrate for subsequent layer-transfer to manufacture a GaN device template for applications including micro-LED.

And while the donor process sequence description has focused upon forming an additional material on a workpiece comprising a single crystal seed GaN layer to form a multi-layer structure, this is also not required. According to alternative embodiments, the additional material could be present on a workpiece. One example of such additional material is single-crystal SiC, (111) silicon, single-crystal and metal films where the material can serve as a seed layer for GaN heteroepitaxial growth.

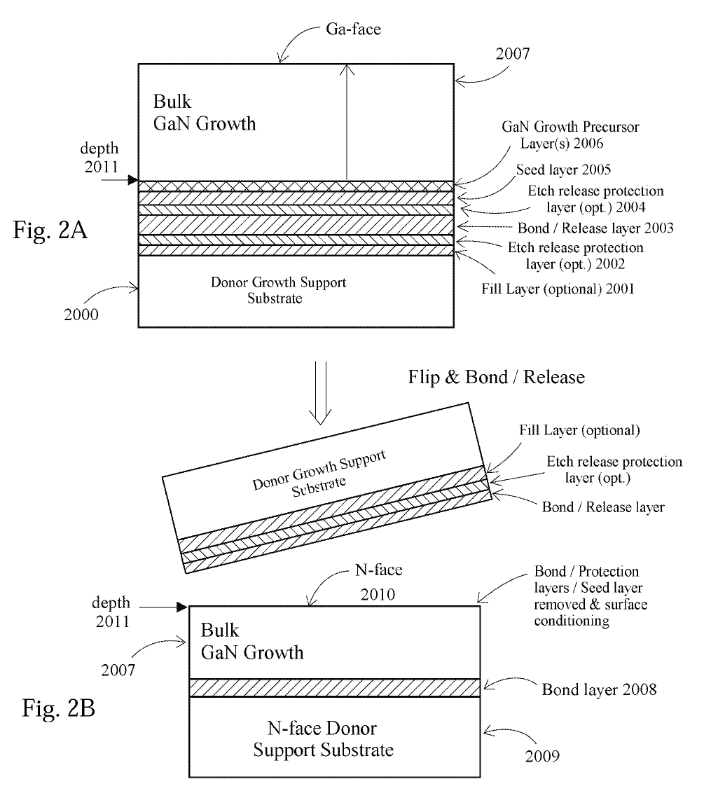

FIG. 2 shows a general structure of a Ga-face donor configuration according to an embodiment. In this particular embodiment, a donor growth support substrate workpiece may comprise a polycrystalline AlN substrate 2000 bearing an optional fill layer such as silicate spin-on-glass or oxide 2001, an optional etch protection layer such as amorphous silicon 2002, a bond/release layer such as an oxide bonding layer 2003, another optional etch protection layer such as amorphous silicon 2004, and a seed layer such as silicon (111) 2005. The oxide bonding layer 2003 may have a thickness, for example, of between about 200-400 nm.

Attached to the oxide bonding layer 2003 and optional etch release protection layer 2004 is a single crystal silicon layer 2005. This single crystal silicon layer has a (111) crystal plane orientation, which may have an intentional off-cut angle of between about 0.1-0.5°.

The single crystal silicon layer may have a thickness of between about 100-200 nm. It may be formed on the template substrate by separation from a high-quality ingot utilizing a layer transfer process, for example in certain embodiments a controlled cleaving process as is described herein. Other layer-transfer processes such as a globally applied thermal cleave layer-transfer process, the SMART-CUT™ process from Soitec S.A. or the ELTRAN™ process from Canon Inc. may be effective.

In one possible embodiment, a thin layer of AlN is in turn formed over the single crystal silicon layer as a GaN growth precursor layer 2006. This AlN layer is formed by MOCVD to a thickness of between about 100-200 nm. Capping the silicon, it serves as a precursor layer to the GaN bulk growth seed layer that is to be grown. Other low-temperature nucleation layer compositions that serve to promote high-quality GaN growth can also be utilized. Incorporated by reference herein for all purposes, is Pinnington et al., “InGaN/GaN multi-quantum well and LED growth on wafer-bonded sapphire-on-polycrystalline AlN substrates by metalorganic chemical vapor deposition”, Journal of Crystal Growth 310 (2008) 2514-2519.

In particular, a GaN seed layer may overlie the AlN capping layer. That GaN seed layer is grown at high quality overlying the AlN layer, also utilizing MOCVD techniques. In this embodiment, both layers form the GaN growth precursor layers 2006.

The surface of the high quality GaN layer offered by the workpiece, in turn serves as a template for the growth of additional GaN material to achieve substantial thicknesses. Where further high quality GaN material 2007 is grown to greater thickness over the GaN seed layer utilizing techniques such as LPE and/or HVPE.

In certain embodiments, additional high quality GaN material grown by LPE would be expected to have a defect density of ˜1×10⁶-5×10⁷ cm⁻². According to some embodiments, additional high quality GaN material grown by HVPE would be expected to have a defect density of ˜1×10⁶-1×10⁷ cm⁻².

The multi-layer workpiece can in turn serve as a donor for separation of high quality GaN layers to be incorporated into electronic devices (such as LEDs, micro-LED and power electronic devices). This may be accomplished by successive implant and controlled cleaving to produce separated GaN layer as described in detail below.

In some embodiments that separated GaN layer may be free standing. In other embodiments that separated GaN layer may be bonded to a temporary handle substrate or permanent target substrate.

It is noted that (111) single crystal silicon on polycrystalline AlN offers a good match in CTE with the overlying grown GaN. Referring to Table 1, the CTE match, dominated by the polycrystalline AlN base substrate would be about 0.2 ppm/° C. This would allow a few hundred microns of additional GaN to be grown without cracking. The single crystal silicon also offers workable lattice matching (˜17%) with the overlying grown GaN.

Materials other than (111) single crystal silicon, however, may offer a more close alignment in lattice spacing with GaN. One example of such a material is single crystal silicon carbide (SiC) for seed layer 2005.

Single crystal SiC is available in a variety of forms, including 3C, 4H, and 6H. The 4H SiC form offers a close lattice match (˜4%) with GaN. Of course, 3C, 6H, or other SiC polytypes may also be utilized according to various embodiments.

Accordingly, an alternative embodiment of a GaN seed workpiece features a 4H SiC layer bonded to an underlying AlN substrate 2000 through a bonding layer 2003 and other possible intermediate layers. That bonding layer may be an oxide bonding layer, including but not limited to spin-on-glass, for example. Again, a MOCVD AlN layer can serve as a precursor layer to the MOCVD GaN seed layer, which in turn serves as the template for thickened GaN which may be grown upon the seed template workpiece utilizing LPE and/or HVPE techniques.

Here it is noted that the AlN precursor of this particular embodiment may be optional. Other low-temperature nucleation layers (or even none) could alternatively be selected depending on the layer itself.

The 4H type SiC layer may be formed by a controlled cleaving from a bulk substrate. Here, that controlled cleaving process may comprise implanting the bulk SiC material with particles, followed by exposure to relatively high temperatures of around 600-900° C. Exemplary particle implantation conditions to form a cleave region in the 4H type SiC are 5-10×10¹⁶ H⁺/cm² at 300° C. implantation temperature, and 180 keV proton energy, 800-900° C. anneal for about 2 hours to achieve cleaving and transfer of the SiC. Incorporated by reference herein for all purposes is Amarasinghe et al., “Properties of H+ Implanted 4H-SiC as Related to Exfoliation of Thin Crystalline Films”, ECS Journal of Solid State Science and Technology, 3 (3) pp. 37-42 (2014).

In order to reduce exposure of the seed workpiece to excessively high thermal budgets (high anneal temperature causing bonded substrate breakage and/or impractically long anneal time) associated with cleaving of SiC, it may be possible to subject an implanted (4H or other polytype) SiC bulk ingot to thermal energy prior to bonding and cleaving. This additional thermal exposure may take the form of annealing and/or laser treatment to weaken the bond between the SiC bulk ingot and remaining SiC material overlying the cleave region formed by the implantation. The purpose of lowering the bonded thermal budget is to allow layer transfer of the SiC film onto the target substrate without breaking the bonded pair. The implanted SiC donor substrate can be thermally annealed to lower the bonded pair cleaving thermal budget using methods explained, for example in U.S. Pat. No. 6,162,705 and/or U.S. Pat. No. 6,013,563, both of which are incorporated by reference in their entireties herein for all purposes. Thermal annealing at a level short of blistering would be effective. As an example, reducing the temperature to a level of about 25-50° C. lower than that required to develop blistering would be effective in limiting the post-bond anneal thermal budget.

Another possible embodiment of a process uses a thin layer of layer-transferred single crystal sapphire (Al₂O₃) as the initial seed layer 2004. The template workpiece comprises an AlN substrate 2000 bearing an oxide bonding layer 2003 as well as other possible intermediate layers. That oxide bonding layer may have a thickness, for example, of between about 200-400 nm.

Attached to the oxide bonding layer 1003 is a sapphire layer 2005. This sapphire layer may have a c-cut orientation in order to provide desirable lattice matching. However, other forms of single crystal sapphire are known and could potentially be used, including a-cut, m-cut, and r-cut oriented materials.

The sapphire layer may have a thickness of between about 0.1-5 μm. It may be formed on the template substrate by separation from a high-quality ingot utilizing a controlled cleaving process as is described herein.

A thin layer of epitaxially grown AlN is in turn formed over the single crystal sapphire layer. This AlN layer is formed by MOCVD to a thickness of between about 50-200 nm. Capping the sapphire, the AlN layer serves as a precursor layer to the GaN seed layer that is to be formed.

A GaN seed layer may overlie the AlN capping layer. That GaN seed layer is formed at high quality overlying the AlN layer, also utilizing MOCVD techniques.

It is noted that a polycrystalline AlN (P-AlN) has a lower CTE mismatch with c-plane GaN than the CTE difference between GaN and sapphire. The thermal conductivity of P-AlN is also substantially higher than sapphire. This will reduce the magnitude of thermal gradients arising in the template workpiece, and improve temperature uniformity during processing.

The surface of the high quality GaN layer offered by the workpiece, in turn serves as a template for the growth of additional GaN material to achieve substantial thicknesses. High quality GaN material may be grown to greater thickness over the GaN seed layer utilizing techniques such as LPE and/or HVPE.

One possible benefit of the use of a layer transferred sapphire layer is that even though there is some (˜13%) lattice mismatch between the sapphire and the GaN grown thereon, the CTE match of the donor growth support substrate 2000 is still an advantage for thick GaN growth. Also, the use of sapphire as growth surface for GaN is well-researched, for example as described by the Pinnington et al. article that is incorporated by reference above.

In summary, embodiments allow the formation of donor workpieces comprising high quality GaN material, by incorporating CTE/lattice compatible materials such as (111) Si, N type SiC, and/or sapphire. Controlled cleaving processes allow those CTE/lattice compatible materials to be separated from large diameter (e.g., >2″) bulk materials, thereby also allowing the overlying grown GaN to exhibit the same corresponding large area. These substrates can in turn be utilized to manufacture GaN-based devices such as LED, micro-LED, power electronics and RF-GaN. These can be cost-effectively fabricated in large-diameter (4″-12″) sizes on insulating or conductive base substrates.

It is further noted that the choice of material for both the workpiece and for the additional layer, can play a role in determining a character of the stress/strain experienced by the additional layer. For example, the choice of workpiece/additional layer may also determine a relative mismatch in coefficient in thermal expansion between them, which in turn can contribute to both the polarity and magnitude of stress/strain arising in the additional layer over a range of temperatures. In view of the above, the workpiece and/or the additional layer materials can be carefully selected to achieve a desired layer of stress/strain within the additional layer over various processing steps.

In specific embodiments, a silicon dioxide or AlN layer can be applied through sputtering or PECVD and optionally densified prior to an implant step. If a film or film stack is applied, it may be of limited total thickness to allow the implant at the selected energy to penetrate into the bulk at the desired cleave depth. Of course there can be other variations, modifications, and alternatives.

The previous donor process sequence develops a thickened donor with an exposed Ga-face. In order to make a final device growth layer with an exposed Ga-face, a double-layer-transfer sequence 1050 in FIG. 1 may be employed. If the Ga-Face donor 1001 was made using a previously grown GaN donor with low TDD on the order of 1×10⁶ cm⁻², this thickened GaN donor 1005 can be released from its base growth support substrate 1002 and mounted on a new support substrate 1007 with the N-face exposed. This N-face donor substrate would have low threading dislocation density (TDD) and allow a potentially more cost-effective single layer-transfer sequence 1060.

As disclosed above, various embodiments leverage the characteristic that the TDD of the grown material decreases as additional material is added. This improves suitability of the additional grown material for incorporation into a micro-LED structure.

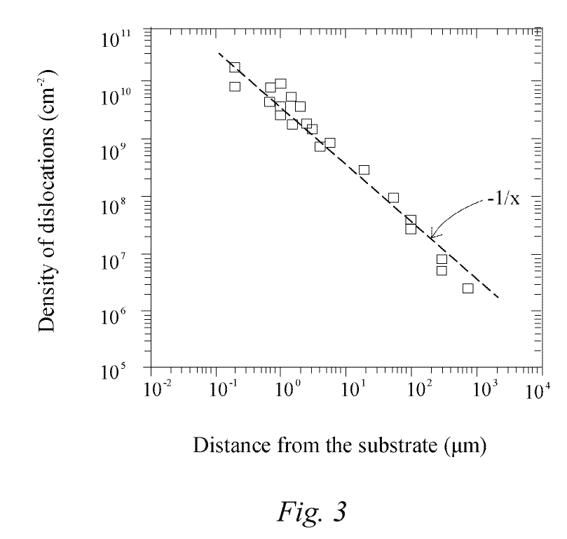

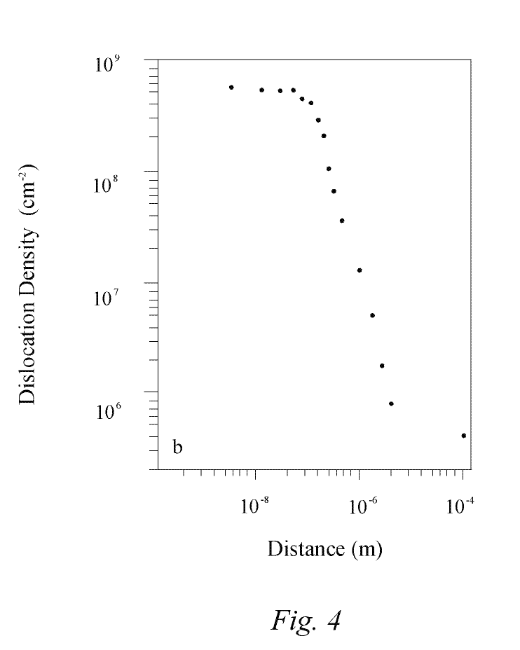

Specifically, FIG. 3 plots dislocation density versus thickness of GaN material grown on sapphire. FIG. 4 plots dislocation density versus thickness of GaN material grown on SiC. FIG. 4 shows the substantially higher TDD reduction rate over growth thickness of a SiC seed layer. This could make the direct use of the SiC—GaN structure practical as a micro-LED structure. In this option described in more detail below, the SiC layer is first bonded onto a suitable growth support substrate and after a few microns of GaN growth (˜1-3 μm), the LED multi-quantum well structure could be grown on GaN having a low TDD on the order of about 1-5×10⁶ cm⁻². It can form a permanent micro-LED integrated structure but if it is to be used as a patterned, singulatable micro-LED structure, the SiC-donor growth substrate bond layer can serve as a release layer.

Referring to portion (B) of FIG. 2, one action for fabricating N-face donor substrates involves separating the prior growth support substrate 2000 and remounting the GaN 2007 N-face up on a new support substrate 2009 and bond layer 2008. This can be accomplished by separating the GaN material 2007 from the Ga-Face assembly in FIG. 2 through chemical etching of the bond/release layer 2003. If this layer is silicon dioxide, hydrofluoric acid (HF) can be used as an effective silicon dioxide etchant. To protect the N-face GaN and growth support substrate from damage, a thin layer of amorphous silicon (a-Si) could be deposited on each side of the bond/release layer to act as an etch stop (layers 2002 and 2004). If the seed layer is silicon (111) as in a particular embodiment, it will perform this function naturally and no additional HF etch stop layer 2004 is necessary on this side of the bond/release layer.

Returning to FIG. 1, another possible advantage of the N-face donor substrate 1006 (other than allowing for a single-step layer-transfer sequence 1060) is the relative ease in which the post-cleave N-face surface can be refreshed for another layer-transfer sequence. It is well known that Ga-Face is chemically very hard and relatively difficult to polish. In contrast, N-Face is chemically weaker and can be polished and made ready for another layer-transfer with significantly less time and effort.

Described now in detail, are use of the donor process sequences in single and double layer transfer process sequences which may be useful for example in fabricating a micro-LED structure incorporating high quality grown GaN material such as is shown in portion (B) of FIG. 2. Specifically, particular embodiments transfer layers of material utilized in electronic devices (e.g., GaN for optoelectronic devices), from a donor to a receiving substrate.

Layer-Transfer Process Sequence

Embodiments of methods to fabricate micro-LED structures utilize layer-transfer processes for both donor formation (to fabricate a cost-effective GaN material source by layering GaN, silicon (111), SiC, sapphire, or other suitable GaN growth seed layers followed by GaN bulk thickening) and final releasable or permanent product to make releasable or permanent micro-LED growth templates. In the succeeding examples, a Ga-face GaN donor is used to make the micro-LED growth templates using two main process sequences: one using a Ga-Face donor with a 2-step layer-transfer process sequence, or the other using an N-Face donor with a 2-step layer-transfer process sequence. In both cases, the result is a Ga-Face final GaN layer bonded onto a target substrate for subsequent processing for micro-LED display fabrication. It is to be understood, however, that other embodiments are possible such as the transfer of an SiC layer that can act as a heteroepitaxial growth seed layer for micro-LED GaN growth of few microns in thickness.

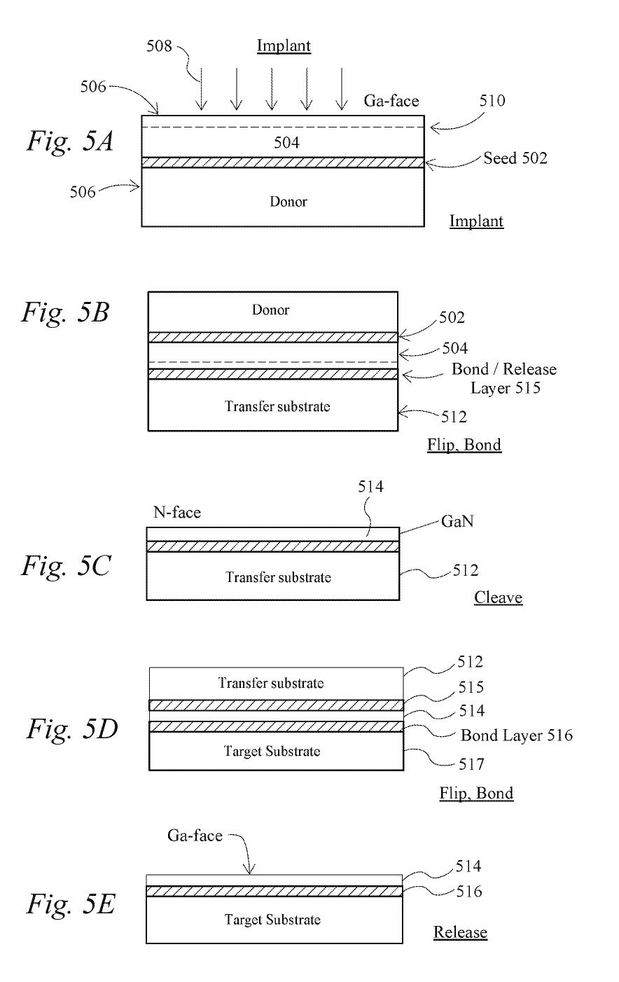

FIGS. 5A-E show a Ga-Face GaN donor substrate using a 2-step layer-transfer process sequence. FIG. 5A shows the GaN exposed surface 506 of the additional grown material exposed to implantation with particles 508. This implantation results in the formation of a subsurface cleave region 510 along which transfer of a layer of the additional material may take place.

FIG. 5B shows the implanted donor is bonded and mounted to a transfer substrate 512 using a bond/release layer 515. The resulting assembly is now cleaved using methods such as controlled-cleave or thermally-induced cleave processes.

FIG. 5C is the intermediate state of the 2-step layer-transfer process where the N-Face is now exposed. Surface polish, etch or other conditioning is optionally made to the N-Face GaN surface followed by the preparation of a bond layer 516 and bonding of the transfer substrate assembly onto a target substrate 517, as shown in FIG. 5D.

The second transfer step may not involve another cleaving, but rather is simply an initial releasable bonding to a transfer substrate, followed by a subsequent bonding to a target substrate. Additional details regarding transfer processes (including two-stage processes), are described in the U.S. Non-provisional patent application Ser. No. 15/186,184, filed Jun. 17, 2016 (published as US 2016/0372628) and incorporated by reference in its entirety herein for all purposes.

After release of the transfer substrate 512, FIG. 5E shows the final layer-transfer assembly with (i) the target substrate 517, bond layer 516, and GaN layer 214, which now has its Ga-Face exposed.

The above description shows the 2-step layer-transfer process sequence. Generally, it is possible to simplify this process sequence by starting with an N-Face donor substrate and thus only require a 1-step layer transfer process sequence make a Ga-Face target substrate assembly.

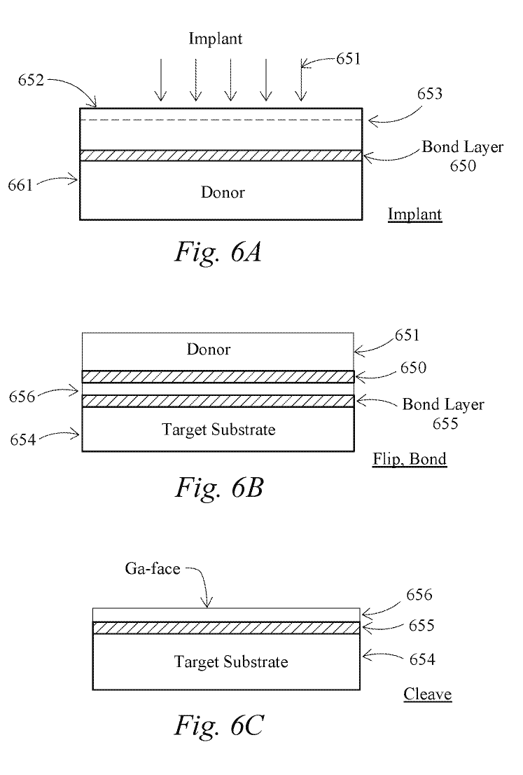

In the case of an N-Face donor and referring to FIG. 2, the surface 2010 originates from about the starting depth 2011 (taking into account polishing and/or conditioning steps removing a few microns of GaN). If the seed layer was c-plane sapphire or silicon (111) for example, this GaN material could potentially have very high TDD levels since it is the point closest to the seed layer. As an example, FIG. 3 would estimate the TDD level to exceed 1×10⁹ cm⁻² if sapphire is used. This issue can be remedied by transferring a lower TDD (˜2-3×10⁶ cm²) GaN as a seed layer 2005 in FIG. 2. This “second generation” GaN layer is also shown as process flow 1010 in FIG. 1 (new donor GaN seed layer). The bulk growth 2007 (FIG. 2) or 1005 (FIG. 1) would then be largely at or lower than the starting GaN TDD level. After the flip and bond process of FIG. 2, the resulting to make an N-Face donor substrate will have TDD levels at or lower than the seed layer 1010. This new donor GaN seed layer process 1010 can be repeated indefinitely in successive GaN growth/layer-transfer/re-growth generations to yield ever lower TDD levels. Essentially, the processes of FIGS. 5 and 6 would be repeated using GaN seed material made from a bulk GaN growth made on a previous (FIG. 5E or 6C) templates. Such successive process cycles (bulk GaN growth “generations”) have lower TDD levels due to the larger aggregate GaN thickness of each GaN bulk growth generation. For example referring to FIG. 3, a first bulk growth of 500 μm from a c-plane sapphire seed layer (generation 0) would drop the TDD level from about 1×10¹⁰ cm⁻² to about 1×10⁷ cm⁻². An additional 500 μm bulk GaN growth from a template made from the top GaN layer using the 2-step process sequence (FIG. 5A-E) would yield a TDD level equivalent to 2×500 μm or 1 mm in total effective thickness. Referring to FIG. 3, the expected TDD level for this generation 1 template would be ˜3×10⁶ cm⁻². At 3 mm total thickness (generation 5), the TDD level would fall below 1×10⁶ cm⁻². This TDD level lowering and GaN quality improvement through successive template re-use and GaN thickening is another aspect offered according to embodiments. If the GaN thickness of a particular generation template is depleted through many successive layer-transfer cycles, additional bulk GaN thickening can be made. However the TDD level should not change appreciably.

Various aspects of different embodiments are now described. The donor substrate and/or seed layer may have lattice and/or CTE properties compatible with the form of GaN that is to be used. Possible candidate substrate materials comprise polycrystal AlN and Mullite.

Bulk GaN may be a crystal of polar or non-polar GaN. In a particular embodiment the bulk GaN (and/or the substrate) may be 2″ wafers, but they are not limited to being of any specific size or dimension.

The substrate may be prepared to receive the transferred GaN. This may involve the formation of an oxide bond layer. The surface of bulk GaN to be bonded may also be treated to have a bond layer added or processed to be more compatible with a bond step.

In particular embodiments, a bond layer can be formed by exposure to oxidizing conditions. In some embodiments this bond layer may be formed by the addition of oxide, e.g., as spin-on-glass (SOG), or other spin on material (e.g., XR-1541 hydrogen silsesquioxane electron beam spin-on resist available from Dow Corning), and/or SiO2 formed by Plasma Enhanced Chemical Vapor Deposition (PECVD) or oxide sputtering techniques.

In certain embodiments the implanted particles are hydrogen ions to form a subsurface cleave region. In some embodiments this cleave region may lie at a depth of between about 10-20 um underneath the surface of the bulk material. In other embodiments the cleave region may lie at a depth of between 0.05-2 um underneath the surface of the bulk material.

Forming a cleave region may depend upon factors such as the target material, the crystal orientation of the target material, the nature of the implanted particle(s), the dose, energy, and temperature of implantation, and the direction of implantation. Such implantation may share one or more characteristics described in detail in connection with the following patent applications, all of which are incorporated by reference in their entireties herein: U.S. patent application Ser. No. 12/789,361 (published as US 2010/0282323); U.S. patent application Ser. No. 12/730,113 (published as US 2010/0178723); U.S. patent application Ser. No. 11/935,197 (published as US 2008/0206962); U.S. patent application Ser. No. 11/936,582 (published as US 2008/0128641); U.S. patent application Ser. No. 12/019,886 (published as US 2009/0042369); U.S. patent application Ser. No. 12/244,687 (published as US 2009/0206275); U.S. patent application Ser. No. 11/685,686 (published as 2007/0235074); U.S. patent application Ser. No. 11/784,524 (published as 2008/0160661); U.S. patent application Ser. No. 11/852,088 (published as US 200/0179547).

In certain embodiments the thickness of material of the implanted surface of the donor is cleaved from the bulk material using the cleave region formed by using relatively high H+ proton implant energies in the MeV range. This produces a detached layer of semiconductor material having a thickness of between about 10-20 um. In other embodiments using bonded layer-transfer, thinner cleaved layers of 0.05-1 um may be used. For producing GaN cleaved films of these thicknesses, lower H+ proton implant energies ranging from approximately 5-180 keV may be used. For example, 40 keV H+ proton energy would produce a GaN cleaved film of approximately 0.25 um in thickness. It is understood that H₂+ can also be utilized for this implant step. In such cases, the dose rate would be doubled while the effective H+ energy would be halved. For example, a 80 keV H₂+ implant could have the same detached layer thickness (range) than a 40 keV H+ implant. However, the dose rate would be double the H+ dose rate for the same implant current.

Bonding may be performed by placing the oxide-bearing surface of the substrate in contact with the implanted face of the bulk GaN, followed by heating. Other acts may be performed at this time, such as touch polishing, plasma treatment and cleaning prior to bonding.

The cleaving may take place utilizing the application of various forms of energy, and may exhibit one or more of the characteristics disclosed in any of the patent applications incorporated by reference above. In a particular embodiment, this cleaving may take place utilizing a compressional force applied in the form of a static gas in a high pressure chamber containing the implanted bulk material. The application of energy in various forms to accomplish cleaving according to particular embodiments is also described in the U.S. Pat. No. 6,013,563 incorporated by reference herein for all purposes. Non-controlled thermal cleaving can also be utilized.

Further steps may involve treatment of the surface of donor and/or seed GaN layer. Such treatment may reduce roughness in the exposed surface, making it more amenable to addition of high quality GaN. Surface treatment can involve thermal, chemical, and/or plasma treatments.

The above sequence of steps provide a method according to certain embodiments of the present invention. Other alternatives can also be provided where steps may be added, one or more steps may be removed, or one or more steps may be provided in a different sequence. For example in an alternative embodiment, the donor could itself include a bonding material, with particle implantation taking place before or after formation of that bonding material.

It is further noted that various embodiments could involve the use of bond-and-release systems, in which the GaN seed layer and substrate are later separated from each other. Additional description of such bond and release approaches are described in U.S. patent application Ser. No. 15/186,185, filed Jun. 17, 2016 and incorporated by reference herein for all purposes.

Surface treatment (e.g. comprising polishing, annealing, and/or cap layer formation) could also include etching processes. Examples of etching processes can include but are not limited to plasma etching, and/or chemical etching. Chemical assisted ion beam etching (CABE) is one example of a type of chemical etching. Wet chemical etching is another example of chemical etching.

The above sequence of steps provide a method according to certain embodiments of the present invention. Other alternatives can also be provided where steps may be added, one or more steps may be removed, or one or more steps may be provided in a different sequence. For example in an alternative embodiment, substrate bonding could take place after the cleaving, with the cleaving resulting in a free standing film in turn bonded to the substrate.

Depending upon the application, according to particular embodiments smaller mass particles are generally selected to decrease the energy requirement for implantation to a desired depth in a material and to reduce a possibility of damage to the material region according to a preferred embodiment. That is, smaller mass particles more easily travel through the substrate material to the selected depth without substantially damaging the material region that the particles traverse through. For example, the smaller mass particles (or energetic particles) can be almost any charged (e.g., positive or negative) and or neutral atoms or molecules, or electrons, or the like. In a specific embodiment, the particles can be neutral or charged particles including ions such as ion species of hydrogen and its isotopes, rare gas ions such as helium and its isotopes, and neon, or others depending upon the embodiment. The particles can also be derived from compounds such as gases, e.g., hydrogen gas, water vapor, methane, and hydrogen compounds, and other light atomic mass particles. Alternatively, the particles can be any combination of the above particles, and or ions and or molecular species and or atomic species. The particles generally have sufficient kinetic energy to penetrate through the surface to the selected depth underneath the surface.

For example, using hydrogen as the implanted species into a GaN surface as an example, the implantation process is performed using a specific set of conditions. Implantation dose ranges of hydrogen from about 5×10¹⁶ to about 5×10¹⁷ atoms/cm², and preferably the dose of implanted hydrogen is less than about 2×10¹⁷ atoms/cm², and may be less than about 5×10¹⁶ atoms/cm². Implantation energy ranges from about 0.5 MeV and greater to about 2 MeV for the formation of thick films useful for opto-electronic applications. In certain bonded substrate embodiments implantation energy may be below 500 keV, for example 5-180 keV. Implantation temperature ranges from about ˜50 to about +500 Degrees Celsius, may be between about 100-500 Degree Celsius, and is preferably less than about 700 Degrees Celsius to prevent a possibility of hydrogen ions from diffusing out of the implanted GaN material. Of course, the type of ion used and process conditions depend upon the application.

Effectively, the implanted particles add stress or reduce fracture energy along a plane parallel to the top surface of the substrate or bulk material at the selected depth. The energies depend, in part, upon the implantation species and conditions. These particles reduce a fracture energy level of the substrate or bulk material at the selected depth. This allows for a controlled cleave along the implanted plane at the selected depth. Implantation can occur under conditions such that the energy state of the substrate or bulk material at all internal locations is insufficient to initiate a non-reversible fracture (i.e., separation or cleaving) in the substrate or bulk material. It should be noted, however, that implantation does generally cause a certain amount of defects (e.g., micro-detects) in the substrate or bulk material that can typically at least partially be repaired by subsequent heat treatment, e.g., thermal annealing or rapid thermal annealing.

Optionally, specific embodiments may include a thermal treatment process after the implanting process. According to a specific embodiment, the present method uses a thermal process ranging from about 150 to about 800 Degrees Celsius for GaN material. In an embodiment, the thermal treatment can occur using conduction, convection, radiation, or any combination of these techniques. The high-energy particle beam may also provide part of the thermal energy and in combination with an external temperature source to achieve the desired implant temperature. In certain embodiment, the high-energy particle beam alone may provide the entire thermal energy desired for implant. In a preferred embodiment, the treatment process occurs to season the cleave region for a subsequent cleave process. Of course, there can be other variations, modifications, and alternatives.

Specific embodiments may include a cleave initiation step, wherein some energy is applied to the cleave portion to begin cleaving. As described in detail below, this cleave initiation could involve the application of different types of energy, having different characteristics.

Additionally, the present invention uses a relatively low temperature during the controlled cleaving process of the thin film to reduce temperature excursions of the separated film, donor, or multi-material films according to other embodiments. This lower temperature approach allows for more material and process latitude such as, for example, cleaving and bonding of materials having substantially different thermal expansion coefficients. In other embodiments, the present invention limits energy or stress in the substrate to a value below a cleave initiation energy, which generally removes a possibility of creating random cleave initiation sites or fronts. This reduces cleave damage (e.g., pits, crystalline defects, breakage, cracks, steps, voids, excessive roughness) often caused in pre-existing techniques. Moreover, embodiments can reduce damage caused by higher than necessary stress or pressure effects and nucleation sites caused by the energetic particles as compared to pre-existing techniques.

In a specific embodiment, the GaN and target substrate are joined or fused together using a low temperature thermal step. The low temperature thermal process generally ensures that the implanted particles do not place excessive stress on the material region, which can produce an uncontrolled cleave action. In one aspect, the low temperature bonding process occurs by a self-bonding process. In particular, one wafer is stripped to remove oxidation therefrom (or one wafer is not oxidized). A cleaning solution treats the surface of the wafer to form O—H bonds on the wafer surface. An example of a solution used to clean the wafer is a mixture of H₂O₂—H₂SO₄. A dryer dries the wafer surfaces to remove any residual liquids or particles from the wafer surfaces. Self-bonding occurs by placing a face of the cleaned wafer against the face of an oxidized wafer.

Alternatively, a self-bonding process occurs by activating one of the wafer surfaces to be bonded by plasma cleaning. In particular, plasma cleaning activates the wafer surface using a plasma derived from gases such as argon, ammonia, neon, water vapor, nitrogen, and oxygen. The activated wafer surface is placed against a face of the other wafer, which has a coat of oxidation thereon. The wafers are in a sandwiched structure having exposed wafer faces. A selected amount of pressure is placed on each exposed face of the wafers to self-bond one wafer to the other.

After bonding the wafers into a sandwiched structure, the method includes a controlled cleaving action to remove the substrate material to provide a thin film of substrate material overlying interface layer(s) on the target substrate. The controlled-cleaving occurs by way of selective energy placement or positioning or targeting of energy sources onto the donor and/or target wafer. For instance, an energy impulse(s) can be used to initiate the cleaving action. The impulse (or impulses) is provided using an energy source which include, among others, a mechanical source, a chemical source, a thermal sink or source, and an electrical source.

The controlled cleaving action is initiated by way of any of the previously noted techniques and others. For instance, a process for initiating the controlled cleaving action uses a step of providing energy to a selected region of the substrate to initiate a controlled cleaving action at the selected depth (z0) in the substrate, whereupon the cleaving action is made using a propagating cleave front to free a portion of the substrate material to be removed from the substrate. In a specific embodiment, the method uses a single impulse to begin the cleaving action, as previously noted. Alternatively, the method uses an initiation impulse, which is followed by another impulse or successive impulses to selected regions of the substrate. Alternatively, the method provides an impulse to initiate a cleaving action which is sustained by a scanned energy along the substrate. Alternatively, energy can be scanned across selected regions of the substrate to initiate and/or sustain the controlled cleaving action.

The detached surface of the film of GaN material may be rough and need finishing. Finishing occurs using a combination of grinding and/or polishing techniques. In some embodiments, the detached surface undergoes lapping and polishing steps using, for examples, techniques such as rotating an abrasive material underlaying the detached surface to remove any imperfections or surface roughness therefrom. A machine such as a “PM5 lapping & polishing system” made by a company called Logitech Limited of Glasgow, Scotland (UK) may provide this technique.

Alternatively, chemical mechanical polishing or planarization (“CMP”) techniques finish the detached surface of the film. In CMP, a slurry mixture is dripped directly to a polishing surface which is attached to a rotating platen. This slurry mixture can be transferred to the polishing surface by way of a chute, which is coupled to a slurry source. The slurry is often a solution containing alumina abrasive particles and an oxidizer, e.g., sodium hypochlorite (NaOCl) or alkaline colloidal silica, which are sold under trade names of SF1 or Chemlox by Logitech Limited. The abrasive is often an aluminum oxide, aluminum trioxide, amorphous silica, silicon carbide, diamond powder, and any mixtures thereof. This abrasive is mixed in a solution of deionized water and oxidizer or the like. The solution may be acidic.

This acid solution generally interacts with the gallium nitride material from the wafer during the polishing process. The polishing process preferably uses a very rigid poly-urethane polishing pad. An example of this polishing pad is one made by Rodel and sold under the trade name of IC-1000. The polishing pad is rotated at a selected speed. A carrier head which picks up the target wafer having the film applies a selected amount of pressure on the backside of the target wafer such that a selected force is applied to the film. The polishing process removes about a selected amount of film material, which provides a relatively smooth film surface for subsequent processing. Depending on whether N-face or Ga-face GaN is to be polished off, slurry with suitable abrasive particle sizes and polishing pads may be used accordingly. As examples, colloidal silica may be used for N-face and sodium hypochlorite may be used for Ga-face.

Other than and/or in addition to polishing, there are a number of other surface preparation options that can be employed to prepare the surface condition of the GaN layer, once it has been transferred from the high quality single crystal GaN bulk substrate to the workpiece. A purpose of this surface preparation is to recover the crystalline quality of the transferred GaN layer that may be compromised or damaged due to the implantation or cleaving step.

a. Thermal annealing in a furnace with or without a protective cap, such as silicon dioxide or AlN. This cap is required if the anneal temperature and ambient gas conditions.
b. For GaN in 1 atm nitrogen ambient, the decomposition temperature of the GaN can be as low as 800-900° C. If a cap layer is used, the anneal temperature without GaN crystal decomposition can be substantially higher.
c. Plasma dry etch to remove a limited thickness of the GaN surface to remove the damaged surface region and allow high-quality epitaxial growth.
d. Wet chemical etch to remove a limited thickness of the GaN surface to remove the damaged surface region and allow high-quality epitaxial growth.
e. Anneal and etch in a MOCVD reactor prior to epitaxial GaN growth. This is similar technique as a. above, except that this can be done in-situ in an MOCVD reactor.
It is of course also possible to use the as-cleaved GaN surface without prior surface preparation if the subsequent epitaxial growth step yields a GaN crystal of sufficient quality. As referenced herein and in the figures, the term “polish” may refer to some sort of surface treatment, which may or may/not include polishing, depending upon the particular embodiment.

Although the above description is in terms of a donor GaN bulk material, others may be used. For example, the donor can be almost any monocrystalline, polycrystalline, or even amorphous type material that can be made to emit light. Additionally, the donor can be made of III/V materials (such as gallium arsenide) or Group IV materials (such as silicon, silicon carbide, and others). The multi-layered substrate may include a GaN layer substrate, a variety of sandwiched layers on a semiconductor substrate, and numerous other types of substrates. Additionally, the above embodiments were offered generally in terms of providing a pulse of energy to initiate a controlled cleaving action. The pulse can be replaced by energy that is scanned across a selected region of the substrate to initiate the controlled cleaving action. Energy can also be scanned across selected regions of the substrate to sustain or maintain the controlled cleaving action. A variety of alternatives, modifications, and variations can be used.

In conclusion, at least the following variations falling within the scope of particular embodiments, are noted. Certain embodiments may utilize various underlying substrates and reflector/barrier/encapsulant layers, including backing technology for enhancing cleaving. According to some embodiments, a donor can comprise GaN, Si, SiC, or other semiconductor material. After cleaving, the material may be polished/prepared for further growth.

Micro-LED Process Sequence

In an embodiment of Ga-Face GaN layer-transferred onto a target substrate with an intermediate bond layer, the substrate can be further processed to a final state for use in micro-LED display manufacturing. The target substrate material options and possibility of integrated layers will be explained further below.

Again referring to an embodiment of c-plane Ga-Face GaN as the micro-LED growth layer made with the layer-transfer process sequences of FIGS. 5 and 6, the following now describes the alternative configurations and process choices to make micro-LED products.

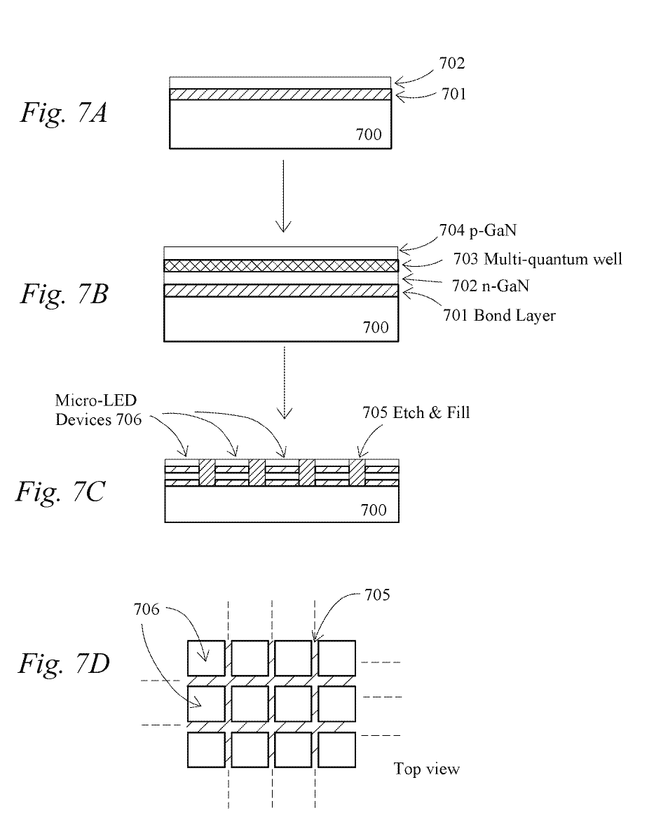

For many configurations, the assemblies of FIG. 5E and FIG. 6C serve as a MOCVD growth template of the micro-LED devices. FIGS. 7A-D show a micro-LED device fabrication sequence, where the template assembly is shown in FIG. 7A as the target substrate 700, bond layer 701 and layer-transferred GaN layer 702.

In FIG. 7B, an LED diode structure is grown on GaN layer 701 using, for example, an MOCVD reactor. Layer 702 is a n-doped layer of GaN (usually silicon doped but other dopants such as germanium is possible). Buffer layers and other process sequences such as high-temperature hydrogen baking and etch-back can be added but are not shown. The active layer is then deposited which is usually a multi-quantum well (MQW) structure that forms the actual diode structure and emits the light. This is followed by a p-GaN contact layer, usually magnesium doped GaN.

To electrically isolate at least one of the two contacts, a lithography step to selectively etch “streets” 705 on the surface is performed, optionally followed by a fill of insulating/passivation material such as oxide. For example, if the pitch is 13 μm with active micro-LED devices 706 of 10 μm on a side, almost 600,000 devices per square centimeters can be manufactured. With an RGB sub-pixel structure (3 micro-LED per RGB pixel) a million pixel display would require about 5 cm² of MOCVD processed area. This high pixel density is cost-effective but also underscores the importance of low defect, high-quality GaN to achieve high manufacturing yields.

FIG. 7C shows the singulation etch through the device and the underlying bond layer 701. If a common electrical contact is desired, the etch step can stop at the n-GaN layer 702, thereby allowing a common contact. It is also possible to alternate the etch and MOCVD growth steps in FIGS. 7B and 7C thereby the etch and fill step is made before the MOCVD growth step.

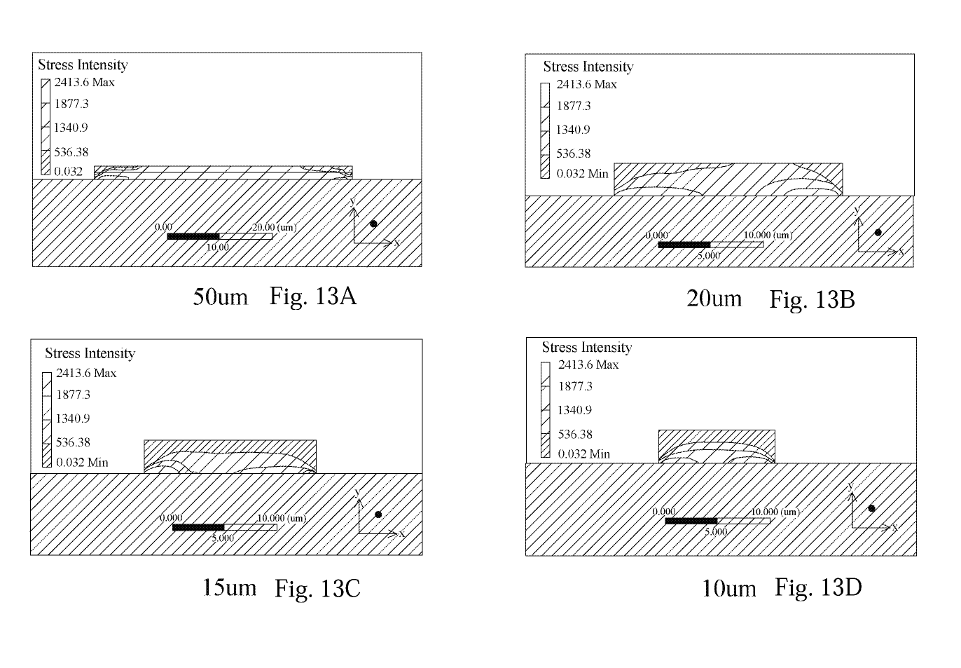

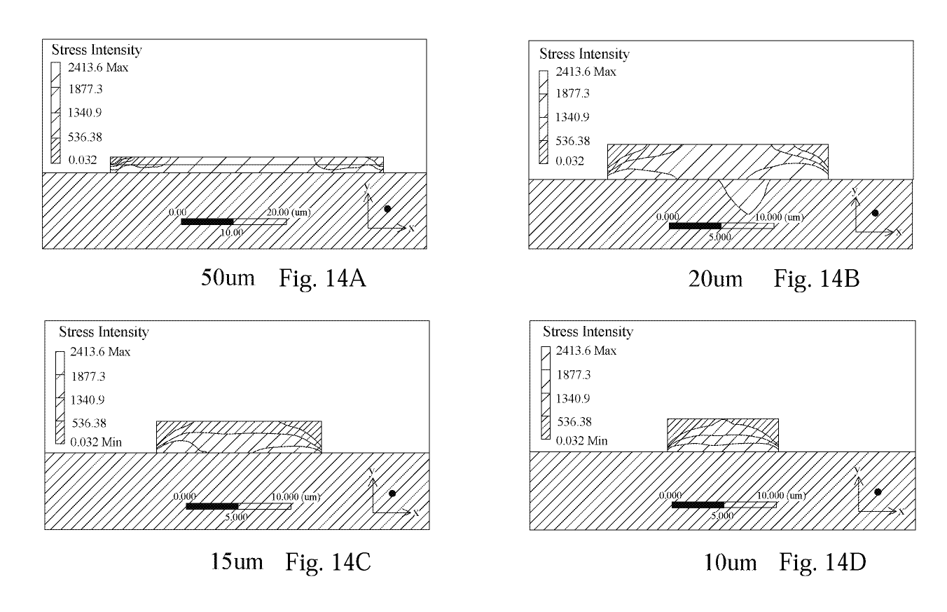

If the micro-LED devices are defined and the starting GaN layer 702 is also etched for example, enhanced stress relaxation of the film during MOCVD growth can be realized. Finite-element analysis (FEA) of the island growth of the GaN device on a CTE-mismatched substrate (sapphire) shows substantially lower stress buildup when devices 706 are smaller than about 50 μm. The lack of a continuous film limits the shear stress buildup. Such techniques could allow the use of previously incompatible substrates because of large CTE-mismatch. Sapphire, silicon, quartz are a few examples of substrates that would have much less stress buildup when pre-MOCVD etch of micro-LED structures is made. FIGS. 13 and 14 show the GaN stress in MPa present on a GaN film transferred at room-temperature and subsequently grown at 1050° C. on Quartz and Sapphire substrates, respectively. Clearly, the film stress present on the films are lower for smaller device size. Stress reduction at the edges are noticed for the 50 μm device but dramatic film stress relaxation occurs for devices lower than about 20 μm, even for a highly CTE-mismatched substrate as quartz.

1. Permanent Target Substrate Configurations

Permanent substrate configurations are defined as the configurations where the individual micro-LEDs are not released from the MOCVD growth substrate and thus the micro-LED device pitch becomes the final pixel pitch of the display. These configurations may be more expensive than the releasable, singulated micro-LED manufacturing sequence described in detail below for many direct view applications. However, there may be advantages in projection and small high-resolution display applications.

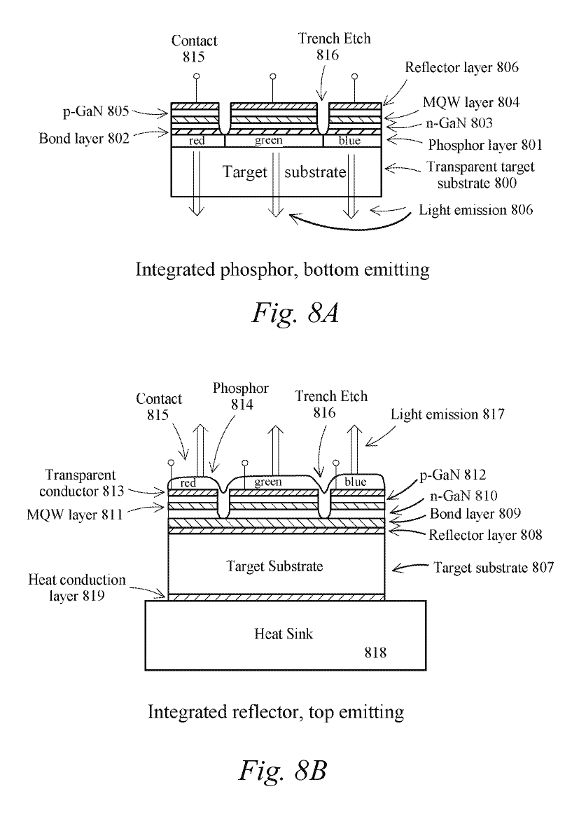

The micro-LED devices fabricated on this substrate are used with either emission of light directed down or up. FIG. 8A shows an example of a micro-LED structure with downwards light emission while FIG. 8B shows an example of a micro-LED structure with upwards light emission.

Referring to FIG. 8A, a downwards light emission configuration would involve the target substrate 800 being transparent and compatible with MOCVD processing environment. Sapphire or Quartz could be used. An integrated phosphor layer could be integrated into the GaN growth template as layer 801 followed by bond layer 802 and the layer-transferred GaN 803, which after the MOCVD growth process would comprise additional n-GaN (balance of layer 803), multi-quantum well layer 804 and p-GaN layer 805. Top contact 806 can be made with a metal that can serve as an electrical contact 815 and a reflector to direct emitted light downwards. Aluminum, silver and other metals can be used and deposited at a lower temperature after the MOCVD growth process. An etch process 816 to functionally isolate the devices can be performed prior to or subsequent to the MOCVD process. Fill of the trench and passivation of the device sidewalls are also possible after the etch process. Bottom electrical contact can be made by a common contact that can be made if the etch process 816 keeps the n-GaN layer continuous and available as a common contact. Other possible contacting methods include integrating rows and columns of electrical wires under the n-GaN layer within the GaN template. Of course, other possible contacting methods can be applied to enable independent application of current to individual micro-LED devices. The integrated phosphor material layer 801 is selected of phosphor material that can survive MOCVD temperature environment without deleterious effects. Silicate phosphors are potential inorganic phoshors that are resistant to high temperature environments. Optionally, the integrated phosphor can be eliminated and the phosphor can be applied on the bottom surface of the target substrate 800 before or after the MOCVD process sequence. Light emission 806 is then directed downwards through the transparent target substrate.

Referring to FIG. 8B, an upwards light emission configuration may use a target substrate 807 with good thermal conduction characteristics since this configuration would likely be utilized in medium to high-power projection display applications. Polycrystalline Aluminum Nitride or Silicon could satisfy this requirement. An MOCVD process compatible reflector layer 808 could be integrated into the GaN growth template followed by bond layer 809 and the layer-transferred GaN 810 which after the MOCVD growth process, would comprise additional n-GaN (balance of layer 810), multi-quantum well layer 811 and p-GaN layer 812. Top contact 813 can be made with a transparent conductor such as Indium Tin Oxide (ITO) followed by an electrical contact 815. An etch process 816 to functionally isolate the devices can be made prior to or subsequent to the MOCVD process. Fill of the trench and passivation of the device sidewalls are also possible after the etch process. Bottom electrical contact can be made to the common contact/reflector 808. One MOCVD compatible reflector/electrical contact material is Molybdenum (Mo). Additional coating can also be added to enhance reflection at the GaN emission spectrum. Other possible contacting methods include integrating rows and columns of electrical wires under the n-GaN layer within the GaN template to contact isolated reflector islands. Of course, other possible contacting methods can be applied to enable independent application of current to individual micro-LED devices. Phosphor material 814 is added above conductor 813 to for the micro-LED configuration with upwards light emission 817.

If an upwards light emission configuration is used as a projection display for example, relatively high current injection operation of the micro-LED devices would utilize an efficient heat sink 818 and heat conduction layer 819 to keep the micro-LED devices at a safe operating temperature.

As an example, a 100-inch, 1000 nit luminance full-HDTV (1920×1080 resolution) projection application with 10 μm×30 μm micro-LED sub-pixel device area, 3 μm trench width would have a source area of approximately 26 cm². Assuming 10% EQE and 2.5V forward voltage at the operating point, each micro-LED will be operated at about 2.7 A/cm², require approximately 8 μA for a total display power of 127 Watts or about 5 W/cm². This is a practical power density for a target substrate 807 with good heat conduction characteristics.

2. Releasable Target Substrate Configurations

For many direct-view display applications, singulating micro-LED devices for redistribution onto a final direct-view display support plate can offer cost and flexibility benefits. Although the cost-effective example of a 100-inch projection display was described above using a permanent target substrate configuration, applying micro-LED to direct-view panels in this manner can be expensive. For example, a 13-inch laptop direct view display would require about 470 cm² of MOCVD area. Assuming about $2/cm² for the MOCVD micro-LED process including the GaN template, the micro-LED cost itself would exceed $900. This approach is also inefficient since at 1000 nit display luminance, the micro-LED devices would be operated at very low current injection levels (less than about 0.002 A/cm²).

If there is an ability to redistribute the micro-LED devices, the micro-LED devices can be operated at higher current density levels and allow a better than 1.0 area ratio (area of pixel to area of micro-LED device). For example, if the same 13-inch laptop screen direct-view display is made from micro-LED devices with 10 μm×10 μm device size and 3 μm trench width, only 10.5 cm² of MOCVD area is required at a cost of approximately $22. In this example, the micro-LED pixels would be operated at a current injection level of 1.4 A/cm² and 0.2 W/cm². In this example, the area ratio is 44 which equals the cost difference between using permanent target substrate and releasable target substrate configurations.

Other examples are listed as below follows (each w/ 1000 nits luminance, 10 μm×10 μm micro-LED device size, 3 μm trench):

| | | MOCVD Area | Area | |
|---|---|---|---|---|
| Display type/pixels | J(A/cm2) | (cm2) | Ratio | Cost |
| 55-inch HDTV | 2.46 | 10.5 | 793 | $21.50 |
| (1920 × 1080) | | | | |
| 32-inch monitor | 0.83 | 10.5 | 269 | $21.50 |
| (1920 × 1080) | | | | |
| 15-inch Laptop | 0.18 | 10.5 | 59 | $21.50 |
| (1920 × 1080) | | | | |
| Smart-phone display | 0.037 | 5.07 | 12 | $10.40 |
| (1334 × 750, 4.7-inch) | | | | |
| Watch display | 0.044 | 0.62 | 14 | $1.26 |
| (390 × 312, 1.65-inch) | | | | |

The interplay between the area ratio and the MOCVD area for different display sizes for the three HDTV resolution display sizes, shows the cost benefit of this technology. To achieve the same luminance at the same micro-LED display size, the current density is selected from 0.18 A/cm² for the 15-inch laptop screen to 2.46 A/cm² for the 55-inch TV size display. The estimated cost for the MOCVD micro-LED devices also demonstrates a potential benefit for this technology.

The micro-LED device approach as described herein can also offer power reduction advantages which can be particularly important for battery powered devices. For example, the smart-phone display example above is the form factor of an iPhone 7 display made by Apple Inc., Cupertino, Calif. Operated at 10% EQE and at the same level as the LCD display specification of 625 nits display luminance, the total expected micro-LED display power is about 175 mW, as compared to the published 1.08 W for the actual iPhone 7 display. This is over 6 times lower power requirement, offering significant product benefits in battery life and if operated at a higher luminance level for direct sunlight readability.

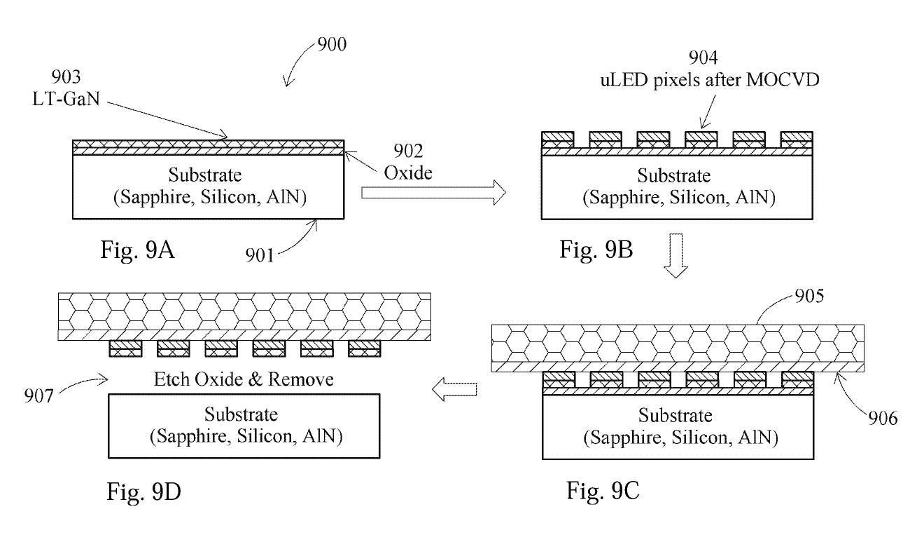

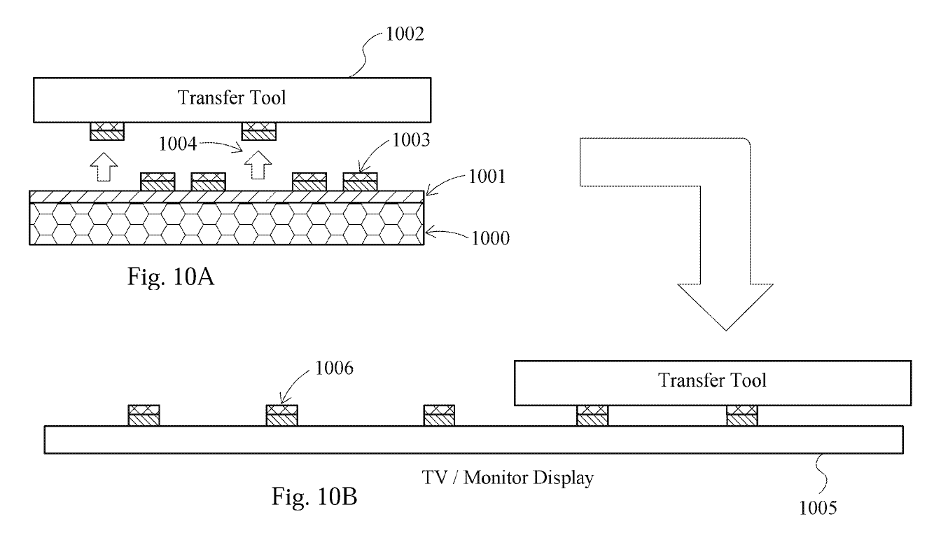

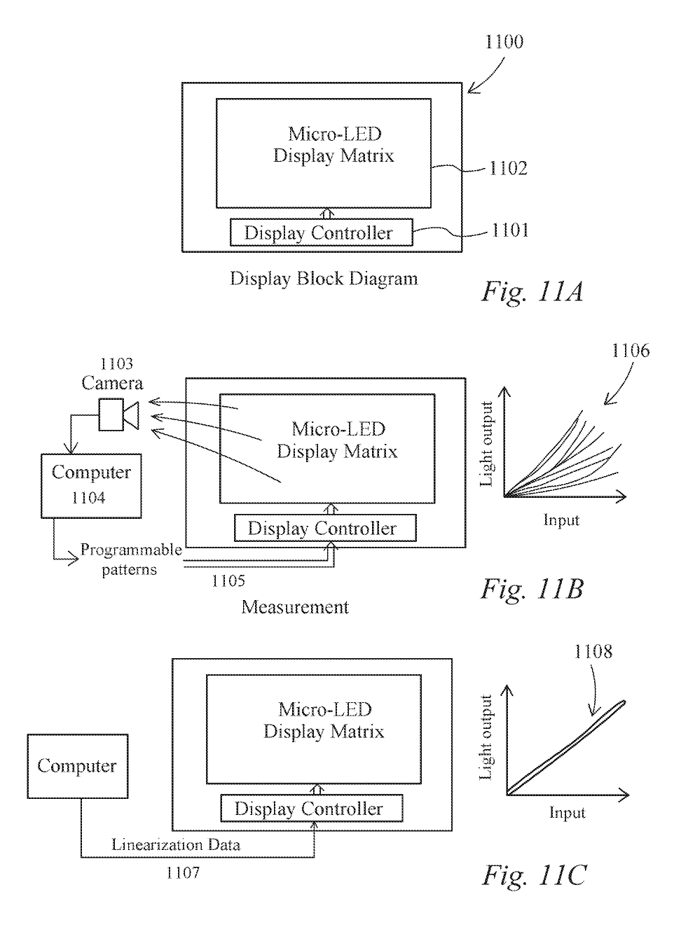

The manufacturing process flow using a releasable target substrate configuration is described in FIGS. 9 and 10. Referring to (A) in FIG. 9, the high-quality GaN MOCVD growth template 900 is made using a suitable substrate 901, a bond layer 902 (oxide in this particular embodiment for subsequent use as a release layer) and the layer-transfer GaN 903. The micro-LED devices are then grown and etched to be made singulatable as shown in (B) of FIG. 9. The micro-LED devices in this particular embodiment are for downward light emission and the top final layer will be a p-GaN contact and light reflector as has been described more fully in FIG. 8A. The top areas of each micro-LED device is then contacted by a pickup plate 905 that has a releasable bond layer 906 as shown in (C) of FIG. 9. Depending on the application, the tackiness of this releasable bond layer 906 can be reversed using electrical, thermal, UV or other means. Global or selectable release methods can also be employed depending on the application.

After attachment of the top surfaces of the micro-LED devices, the micro-LED devices are detached from target substrate 907 as shown in (D) of FIG. 9. In this example using a bond layer 902 composed of silicon dioxide, a hydrofluoric acid (HF) based etchant can be effective in removing the bond layer 902 while the micro-LED devices stay attached to the pickup plate 905. If there may be contact by the etchant with the pickup plate 905 and releasable bond layer 906, these are made sufficiently resistant to the etchant until the separation process is completed.

FIG. 10 shows the final steps in mounting the micro-LED devices onto a direct-view display backplane. Reference (A) of FIG. 10 shows the pickup of certain micro-LEDs from the pickup plate 1000 onto a transfer tool 1002 by selectively adjusting the tackiness of the micro-LED devices between the transfer tool and the pickup plate in (A). Micro-LEDs such as micro-LED 1004 are picked up by the transfer tool, while other micro-LEDs such as micro-LED 1003 remain on the pickup plate. Possible methods to effectuate this selection process can include local thermal impulses to lower the tackiness of layer 1001 and/or locally increase the tackiness of the transfer tool (i.e. local electrostatics, etc.). Once the micro-LEDs are selected, they can then be mounted onto a direct-display backplane 1005 at the appropriate pitch where each micro-LED 1006 is then separated and contacted per the desired pixel pitch of the display. In this example, the micro-LED reflector side is now downwards on the display backplane 1005 and light is directed upwards. RGB phosphors can now be applied to each micro-LED for down-conversion (not shown) to generate the red/green/blue color gamut of the pixel.

This particular example uses flat plates. But, to facilitate mass-production, the transfer tool could utilize rollers and successive move and pickup steps such as in (A) of FIG. 10 to allow mass-production methods to be fully utilized.

To improve yield, multiple micro-LED devices can be mounted within each sub-pixel. Depending on the failure mechanism, different contacting methods can be employed to lower manufacturing costs and improve yields. For example, micro-LED failures are more likely to be exhibited as a short circuit than an open circuit. If two micro-LEDs are mounted side by side, they may be connected in series to enable at least one device to function when the other is shorted. Driving the micro-LED by current could be employed in this configuration. Alternatively, if a voltage drive scheme is used, ballast resistors and parallel micro-LED connection may be used.

Although embodiments improve the quality of the GaN material and lower defect density, there may remain some non-uniformity in output light level as a function of drive level (current or voltage input). Such non-uniformity may arise where multiple micro-LED devices are connected within a sub-pixel to improve manufacturing yield. Depending on the drive and micro-LED redundant connection scheme used, individual sub-pixel failures may show as dimmer or brighter than surrounding sub-pixels. To remedy this possible issue and normalize the display input/output function for a collection of pixels, FIGS. 11A-C describe steps that may be utilized during manufacturing.

FIG. 11A shows a direct-view display utilizing micro-LEDs according to an embodiment. The display 1100 comprises a display controller with programmable memory 1101 driving a micro-LED display matrix 1102.

During the manufacturing process, a camera 1103 is used to radiometrically measure the intensity of each micro-LED pixel as a result of programmable patterns 1105 fed to the display via a computer 1104 (see FIG. 11B). The measurement is to map the light output of each micro-LED sub-pixel 1106 in response to varying input signal (grey scale of each sub-pixel). After computing the inverse response function necessary to normalize the display for uniform light output as a function of uniform drive input (shown as reference number 1108 in FIG. 11C), the display controller is programmed with the linearization data 1107. This can be accomplished during the manufacturing process as one of a series of final quality assurance steps. Other quality and yield methods can be utilized such as using image capture and processing to measure the presence of micro-LEDs in each pixel area and perform interim functional testing of the micro-LEDs before phosphor application, for example.

The above was described with GaN as a LED material. Other materials can be utilized, especially when color (RGB) micro-LED are used instead of down-converted UV LEDs such as GaN. For example, layer-transfer of other III-V materials to make color micro-LED displays are possible. Some possible alternative materials are listed below:
Red LED: AlGaAs, GaAsP, AlGaInP
Green LED: GaP, AlGaInP, AlGaP
Blue LED: ZnSe, InGaN, SiC

Starting MOCVD III-V and II-VI materials could include GaAs and GaP substrates. Once these layers are transferred onto a target substrate, the MOCVD growth, singulation and mounting onto their respective RGB sub-pixel areas would yield a high-quality micro-LED direct-view display.

Clause 1. A method comprising:

growing a crystalline semiconductor material over a donor substrate, a threading dislocation density (TDD) of the material declining with thickness;
implanting a plurality of particles into an exposed face of the material to create a subsurface cleave region;
bonding the exposed face to a substrate;
applying energy to cleave the material along the cleave plane to leave a layer bonded to the substrate; and
processing the layer for incorporation into a micro-light emitting diode (LED) structure.

Clause 2. A method as in clause 1 wherein:

the material comprises c-plane polar GaN; and
the exposed face comprises a N face of the c-plane polar GaN.

Clause 3. A method as in clause 1 wherein:

the material comprises c-plane polar GaN; and
the exposed face comprises a Ga face of the c-plane polar GaN.

Clause 4. A method as in clause 1 wherein the bonding comprises a temporary bonding and the substrate comprises a handle substrate, the method further comprising:

permanently bonding the layer to a target substrate; and
releasing the layer from the handle substrate, wherein processing the layer comprises incorporating the target substrate into the micro-LED structure.

Clause 5. A method as in clause 4 wherein the micro-light emitting diode (LED) structure generates colored light with a down conversion material.

Clause 6. A method as in clause 5 wherein the down conversion material comprises phosphor.

Clause 7. A method as in clause 6 wherein the phosphor is an integrated layer within the target substrate.

Clause 8. A method as in clause 1 wherein a TDD of the layer is 1×107 cm-2 or lower.

Clause 9. A method as in clause 1 wherein the donor substrate includes at least one of GaN, silicon carbide, silicon, sapphire, and AlN as an epitaxial growth seed layer having an exposed surface.

Clause 10. A method as in clause 9 wherein silicon carbide is 4H or 6H polytype.

Clause 11. A method as in clause 9 wherein silicon is single crystal and (111) orientation.

Clause 12. A method as in clause 9 wherein the epitaxial growth seed layer is applied using a bond and cleave process.

Clause 13. A method as in clause 12 wherein the bond and cleave process comprises a controlled-cleave layer-transfer process.

Clause 14. A method as in clause 12 wherein the bond and cleave process comprises a globally applied thermal cleave layer-transfer process.

Clause 15. A method as in clause 12 wherein the epitaxial growth seed layer is bonded using a releasable bond layer.

Clause 16. A method as in clause 15 wherein the releasable bond layer is released using an etchant.

Clause 17. A method as in clause 16 wherein the etchant comprises hydrofluoric acid (HF).

Clause 18. A method as in clause 16 wherein an etch stop layer is present on one or both sides of the releasable bond layer.

Clause 19. A method as in clause 18 wherein the etch stop layer comprises amorphous silicon.

Clause 20. A method as in clause 15 wherein the releasable bond layer comprises silicon dioxide.

Clause 21. A method as in clause 1 wherein the donor substrate comprises polycrystalline aluminum nitride.

Clause 22. A method as in clause 1 wherein the crystalline semiconductor material includes at least one of GaN, GaAs, ZnSe, SiC, InP, and GaP.

Clause 23. A method as in clause 1 wherein the micro-light emitting diode (LED) structure generates colored light with a down conversion material.

Clause 24. A method as in clause 23 wherein the down conversion material comprises phosphor.

Clause 25. A method as in clause 24 wherein the phosphor is an integrated layer within the substrate.

Clause 26. A method as in clause 1 wherein processing the layer comprises removing the layer in selected regions to define a plurality of separate optically active regions.

Clause 27. A method as in clause 26 wherein the removing comprises a lithographic process.

Clause 28. A method as in clause 26 wherein the removing comprises applying an energy beam.

Clause 29. A method as in clause 26 wherein:

the processing further comprises MOCVD; and
the MOCVD is performed after the removing.

Clause 30. A method as in clause 1 wherein the applying energy comprises a controlled-cleave layer-transfer process.

Clause 31. A method as in clause 1 wherein the applying energy comprises a globally applied thermal cleave layer-transfer process.

Clause 32. A method as in clause 1 wherein the implanting is an ion implant step with particles selected from hydrogen or helium having ion energy between about 20 keV-750 keV.

Clause 33. A method as in clause 1 wherein:

the processing comprises MOCVD performed prior to the implantation; and
the implanting is an ion implant with particles selected from hydrogen or helium having ion energy between about 200 keV-750 keV.

Clause 34. A method as in clause 1 wherein the micro-light emitting diode (LED) structure is driven by a display controller incorporating a programmable lookup table for at least 2 micro-LED pixels.

Clause 35. A method as in clause 34 wherein an output light to input drive function for each micro-LED is measured using a camera and stored in a computer memory to develop a first transfer function.

Clause 36. A method as in clause 35 wherein a computer analyzes the first transfer function to calculate a linearization table that is programmed into the display controller to normalize and linearize an output light transfer function.

Clause 37. A method as in clause 36 wherein a resulting light uniformity across a plurality of pixels is within about 10%.

Clause 38. A method as in clause 37 wherein a resulting light uniformity across the plurality of pixels is within about 5%.

Clause 39. A method as in clause 38 wherein a resulting light uniformity across the plurality of pixels is within about 2%.

Clause 40. A method as in clause 37 wherein the substrate is selected from quartz, silicon, polycrystalline AlN, and sapphire.

Clause 41. A method as in clause 1 wherein the micro-light emitting diode (LED) structure generates colored light without a down conversion material.

Clause 42. A method as in clause 1 wherein processing the layer comprises:

forming a plurality of discrete pixels separated by streets; and
transferring the plurality of discrete pixels en masse to a target substrate.

Clause 43. A method as in clause 42 wherein the target substrate includes phosphor.

Clause 44. A method as in clause 1 wherein processing the layer comprises:

forming a plurality of discrete pixels separated by streets; and
selectively transferring fewer than the entire plurality of discrete pixels to a target substrate.

Clause 45. A method as in clause 44 wherein the selectively transferring utilizes a transfer tool.

Clause 46. A method as in clause 44 wherein the selectively transferring utilizes a release layer.

Clause 47. A method comprising:

growing a crystalline semiconductor material over a donor substrate, a threading dislocation density (TDD) of the material declining with thickness;
bonding the exposed face to a target substrate;
releasing the material to leave a thickness bonded to a substrate with a second exposed face; and
processing the substrate for incorporation into a micro-light emitting diode (LED) structure.

Clause 48. A method as in clause 47 wherein:

the material comprises c-plane polar GaN;
the exposed face comprises a Ga face of the c-plane polar GaN; and
a second exposed face comprises a N face of the c-plane polar GaN.

Clause 49. A method comprising:

providing a crystalline semiconductor material;
implanting a plurality of particles into an exposed face of the material to create a subsurface cleave region;
bonding the exposed face to a substrate;
applying energy to cleave the material along the cleave plane to leave a layer bonded to the substrate; and
processing the layer for incorporation into a micro-light emitting diode (LED) structure.

Clause 50. A method as in clause 49 wherein the crystalline semiconductor material includes at least one of GaN, GaAs, ZnSe, SiC, InP, and GaP.

Clause 51. A method as in clause 50 wherein the micro-light emitting diode (LED) structure generates colored light without a down conversion material.

Clause 52. A method as in clause 49 wherein processing the layer comprises:

forming a plurality of discrete pixels separated by streets; and
transferring the plurality of discrete pixels en masse to a target substrate.

Clause 53. A method as in clause 52 wherein the target substrate includes phosphor.

Clause 54. A method as in clause 49 wherein processing the layer comprises:

forming a plurality of discrete pixels separated by streets; and
selectively transferring fewer than the entire plurality of discrete pixels to a target substrate.

Clause 55. A method as in clause 54 wherein the selectively transferring utilizes a transfer tool.

Clause 56. A method as in clause 54 wherein the selectively transferring utilizes a release layer.

Certain embodiments may further disclose a protective layer for laser removal of transferred material. A protective layer allows removing a previously-transferred material by precise local application of a laser, without incurring damage to an underlying handle substrate. According to one embodiment, the protective layer comprises silicon oxide overlying a sapphire handle substrate, to which a high quality material (e.g., group III/V) has been transferred. Individual islands of the group III/V material are isolated by patterning streets (e.g., utilizing lithographic techniques). Subsequent application of energy from a laser through the optically transparent handle substrate and through at least a portion of the protective layer serves to avoid damaging the underlying handle substrate. The process allows island(s) of the high quality III/V material to be selectively freed and moved to a target substrate. Protecting the (relatively expensive) handle substrate from damage in this manner facilitates its reuse to receive additional high quality group III/V material layer-transferred from a donor. Certain embodiments may be particularly suited to protecting a sapphire handle substrate during movement of islands of GaAs or GaN to form micro-Light Emitting Diode (μ-LED) pixels onto a target.

One approach may be to first form a layer of material on a high quality donor substrate—e.g., utilizing epitaxial growth techniques. Then, a portion of the grown material may be layer-transferred to a handle substrate for further processing.

Examples of such further processing can include the formation of streets (e.g., by lithography) to define isolated islands of high quality grown material corresponding to individual pixels or components thereof. Another example of further processing of material on the handle may be the selective transfer of individual islands to a target substrate for incorporation into an optical device. However, such further processing of material can damage the handle substrate, which may be expensive.

Accordingly, embodiments relate to the use of a protective layer for laser removal of transferred material. The protective layer allows removing a previously-transferred material by precise local application of a laser, without incurring damage to an underlying handle substrate.

In one embodiment, the protective layer comprises silicon oxide overlying a sapphire handle substrate, to which a high quality group III/V material has been transferred. Individual islands of the group III/V material are isolated by patterning streets (e.g., utilizing lithographic techniques), with the protective layer optionally serving as an effective stop to avoid damaging the underlying handle substrate. Subsequent application of energy from a laser through the optically transparent handle substrate allows island(s) of the high quality III/V material to be selectively freed and moved to a target substrate.

Protecting the (relatively expensive) handle substrate from damage in this manner facilitates its reuse to receive additional high quality group III/V material layer-transferred from a donor. Certain embodiments may be particularly suited to protecting a sapphire handle substrate during movement of islands of GaAs or GaN to form micro-Light Emitting Diode (μ-LED) pixels onto a target.

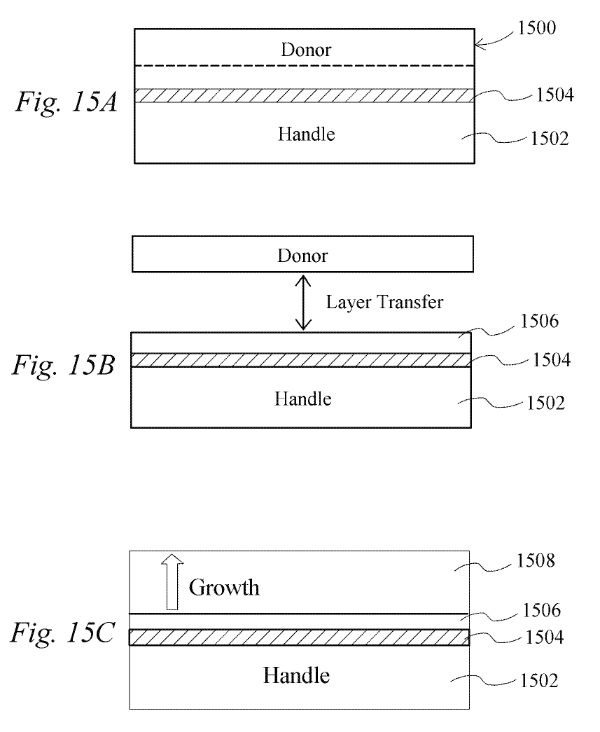

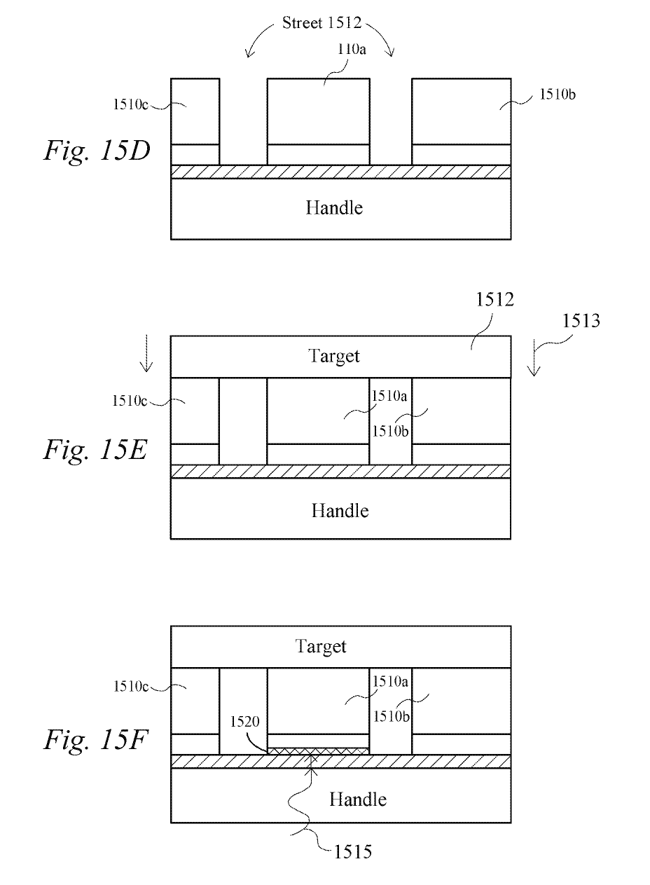

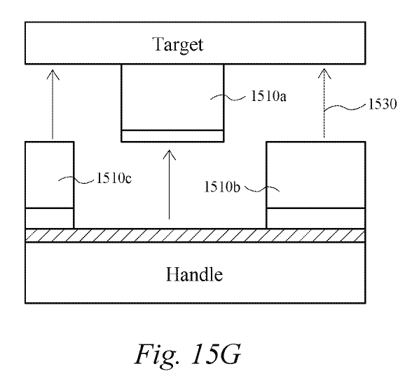

FIGS. 15A-G show simplified cross-sectional views of an embodiment of a process flow utilizing a protective layer. Specifically, FIG. 15A shows a donor 1500 comprising high quality group III/V material, that is bonded to a handle substrate 1502 via an intervening protective layer 1504.

The high quality group III/V material of the donor may be produced by epitaxial growth upon a template and/or seed layer, as described in the U.S. Provisional Patent Applications 62/370,169 filed Aug. 2, 2016, 62/378,126 filed Aug. 22, 2016, and 62/421,149 filed Nov. 11, 2016, each of which are incorporated by reference in their entireties herein for all purposes.

In certain embodiments the protective layer may comprise silicon oxide. Such a silicon oxide protective layer may be formed in a variety of ways, including but not limited to deposition, plasma exposure in an oxygen ambient, and spin-on-glass (SOG) techniques.

FIG. 15B shows a subsequent layer transfer step, wherein a layer 1506 of the high quality group III/V material is separated from the donor and remains bonded to the protective layer and the handle. This layer transfer may be accomplished in a variety of ways, for example utilizing particle implantation followed by a controlled cleaving process as described at least in U.S. Pat. No. 6,013,563 which is incorporated by reference in its entirety herein for all purposes. Other layer transfer approaches can include but are not limited to the SMART-CUT™ process from Soitec S.A. or the ELTRAN™ process from Canon Inc.

FIG. 15C shows subsequent formation of additional high quality group III/V material 1508 over the layer-transferred layer 1506. Again, this additional material can be formed by epitaxial growth techniques such as Metallo-Organic Chemical Vapor Deposition (MOCVD) or Hydride Vapor Phase Epitaxy (HVPE).

FIG. 15D shows patterning of individual islands 1510a, 1510b, 1510c of high quality group III/V material upon the handle substrate. This may be accomplished by forming streets 1512 separating adjacent islands.

Particular embodiments may form the streets by lithography. Such lithographic processes may involve patterning photoresist (negative or positive), followed by exposure and development. Etching in regions revealed by the developed resist (negative or positive) may remove the high quality group III/V material in the streets.

Significantly, the presence of the protective layer 1504 may protect the underlying handle substrate from degradation during street formation. That is, the etching process leading to removal of the group III/V material may be highly selective relative to the protective layer (e.g., SiO2), but not as selective relative to the underlying handle substrate (e.g., sapphire).

Hence, absent the protective layer the handle substrate could be damaged by etching to form the streets. Application of the protective layer in accordance with embodiments may serve to avoid such damage to the handle.

Although not shown in the figures, upon completion of the formation of streets, any developed photoresist mask could be removed—e.g., by ashing. The presence of the protective layer would also serve to prevent damage to the handle by such a process of lithographic mask removal.

While the above has described street formation as an etching process, this is not required. Alternative embodiments could employ other types of approaches in order to form streets. Examples can include but are not limited to subtractive processes involving removal of material, e.g., by ablation, vaporization, and/or decomposition.

FIGS. 15E-15G show the subsequent transfer of an individual island from the handle to a target substrate 1512. Specifically, in FIG. 15E the target is 1513 bonded to the handle substrate bearing the individual islands.

In FIG. 15F, the particular island 1510a is selectively exposed to optical energy 1515 communicated through the transparent handle substrate. According to certain embodiments the optical energy may take the form of a laser beam precisely applied specifically to the location of an island of group III/V material that is to be transferred to the target substrate.

The applied optical energy also traverses at least a portion of the protective layer. Absorption of the optical energy between the handle substrate and the group III/V material results in a separation of that group III/V material from the handle substrate.

In certain embodiments the separation may occur via a localized decomposition 1520 of the group III/V material. One example of such decomposition may occur as GaAs changes into Ga and As at temperatures exceeding about 650° C.

Other thermally-induced physical (e.g., phase change) and/or chemical transformations may form the basis for selective separation of islands to a target substrate.

FIG. 15G shows the resulting lift-off step, wherein the target substrate is removed 1530, taking with it the now-separated island 1510a. The other islands 1510b, 1510c remain bound to the handle substrate, and are available for subsequent selective transfer to a target substrate.

One method to accomplish this selective transfer is to make the surface of the target substrate sufficiently sticky. The tackiness of the target substrate would be selected to be higher than the release strength necessary to break off and lift a device after the application of optical energy 1515 but lower than the breaking strength of the devices without the application of optical energy 1515. An electrostatic chuck mounted on the target substrate can also be an effective method to imbue a certain stickiness.

In the manner just shown, individual islands of high quality group III/V material may be selectively transferred from a handle substrate to a target substrate for incorporation into optical devices (e.g., discrete μ-LED pixels). Moreover, this may be accomplished without damaging the handle substrate, rendering it suited for use in subsequent layer transfer steps.

The potential benefits of large-area, cost-effective and high-quality Group III/V growth layers (e.g., GaAs, GaN) for micro-LED manufacturing are numerous.

The large substrate size templates made possible by various embodiments may permit cost-effective manufacturing of high-quality micro-LED devices compatible with high-volume manufacturing of projection and direct view displays of a large variety of sizes.

Clause 1A. A method comprising:

providing a handle substrate;
disposing a protective layer between the handle substrate and a group III/V material;
transferring a layer of the group III/V material to the protective layer;
growing additional group III/V material from the layer;
patterning streets through the layer and the additional group III/V material to form islands on the handle substrate, the patterning stopping on the protective layer; and
transferring an island from the handle substrate to a transfer substrate.

Clause 2A. A method as in clause 1A wherein the protective layer comprises silicon oxide.

Clause 3A. A method as in clause 1A wherein the handle substrate comprises sapphire.

Clause 4A. A method as in clause 1A wherein the streets are patterned by a lithographic technique.

Clause 5A. A method as in clause 4A wherein the lithographic technique comprises etching the group III/V material.

Clause 6A. A method as in clause 4A wherein the group III/V material comprises GaAs.

Clause 7A. A method as in clause 4A wherein the group III/V material comprises GaN.

Clause 8A. A method as in clause 4A wherein transferring the island comprises applying optical energy through the handle substrate and at least a portion of the protective layer.

Clause 9A. A method as in clause 8A wherein the optical energy comprises a laser beam.

Clause 10A. A method as in clause 8A wherein the optical energy induces a chemical change in the group III/V material.

Clause 11A. A method as in clause 1A wherein transferring the layer of the group III/V material comprises implanting particles into the donor substrate followed by a cleave process.

Clause 12A. A method as in clause 1A wherein the disposing comprises bonding the group III/V material to the handle substrate bearing the protective layer.

Clause 13A. A method as in clause 1A wherein the disposing comprises bonding the group III/V material bearing the protective layer to the handle substrate.

Clause 14A. A method as in clause 1A wherein the disposing comprises bonding the group III/V material bearing a part of the protective layer to the handle substrate bearing another part of the protective layer.

Clause 15A. An apparatus comprising:

a handle substrate substantially transparent to incident optical energy;
a protective layer overlying the handle substrate; and
a layer transferred group III/V material overlying the protective layer, the group III/V material separating from the handle substrate in response to the incident optical energy.

Clause 16A. An apparatus as in clause 15A wherein the handle substrate comprises sapphire.

Clause 17A. An apparatus as in clause 15A wherein the protective layer comprises silicon oxide.

Clause 18A. An apparatus as in clause 15A wherein the layer transferred group III/V material comprises GaAs.

Clause 19A. An apparatus as in clause 15A wherein the layer transferred group III/V material comprises GaN.

While the above is a full description of the specific embodiments, various modifications, alternative constructions and equivalents may be used. Although the above has been described using a selected sequence of steps, any combination of any elements of steps described as well as others may be used. Additionally, certain steps may be combined and/or eliminated depending upon the embodiment. Furthermore, the particles of hydrogen can be replaced using co-implantation of helium and hydrogen ions or deuterium and hydrogen ions to allow for formation of the cleave plane with a modified dose and/or cleaving properties according to alternative embodiments. Still further, the particles can be introduced by a diffusion process rather than an implantation process. Of course there can be other variations, modifications, and alternatives. Therefore, the above description and illustrations should not be taken as limiting the scope of the present invention which is defined by the appended claims.

What is claimed is:

1. A method comprising:
growing a crystalline semiconductor material over a donor substrate, a threading dislocation density (TDD) of the material declining with thickness;
implanting a plurality of particles into an exposed face of the material to create a subsurface cleave region;
bonding the exposed face to a substrate;
applying energy to cleave the material along the cleave plane to leave a layer bonded to the substrate; and
processing the layer for incorporation into a micro-light emitting diode (LED) structure.

2. A method as in claim 1 wherein:
the material comprises c-plane polar GaN; and
the exposed face comprises a N face of the c-plane polar GaN.

3. A method as in claim 1 wherein:
the material comprises c-plane polar GaN; and
the exposed face comprises a Ga face of the c-plane polar GaN.

4. A method as in claim 1 wherein the bonding comprises a temporary bonding and the substrate comprises a handle substrate, the method further comprising:
permanently bonding the layer to a target substrate; and
releasing the layer from the handle substrate, wherein processing the layer comprises incorporating the target substrate into the micro-LED structure.

5. A method as in claim 4 wherein the micro-light emitting diode (LED) structure generates colored light with a down conversion material.

6. A method as in claim 1 wherein a TDD of the layer is 1×10⁷ cm⁻² or lower.

7. A method as in claim 1 wherein the donor substrate includes at least one of GaN, silicon carbide, silicon, sapphire, and AlN as an epitaxial growth seed layer having an exposed surface.

8. A method as in claim 1 wherein the donor substrate comprises polycrystalline aluminum nitride.

9. A method as in claim 1 wherein the crystalline semiconductor material includes at least one of GaN, GaAs, ZnSe, SiC, InP, and GaP.

10. A method as in claim 1 wherein the micro-light emitting diode (LED) structure generates colored light with a down conversion material.

11. A method as in claim 1 wherein processing the layer comprises removing the layer in selected regions to define a plurality of separate optically active regions.

12. A method as in claim 11 wherein:
the processing further comprises MOCVD; and
the MOCVD is performed after the removing.

13. A method as in claim 1 wherein:
the processing comprises MOCVD performed prior to the implantation; and
the implanting is an ion implant with particles selected from hydrogen or helium having ion energy between about 200 keV-750 keV.

14. A method as in claim 1 wherein processing the layer comprises:
forming a plurality of discrete pixels separated by streets; and
transferring the plurality of discrete pixels en masse to a target substrate.

15. A method as in claim 1 wherein processing the layer comprises:
forming a plurality of discrete pixels separated by streets; and
selectively transferring fewer than the entire plurality of discrete pixels to a target substrate.

16. A method comprising:
growing a crystalline semiconductor material over a donor substrate, a threading dislocation density (TDD) of the material declining with thickness;
bonding the exposed face to a target substrate;
releasing the material to leave a thickness bonded to a substrate with a second exposed face; and
processing the substrate for incorporation into a micro-light emitting diode (LED) structure.

17. A method as in claim 16 wherein:
the material comprises c-plane polar GaN;
the exposed face comprises a Ga face of the c-plane polar GaN; and
a second exposed face comprises a N face of the c-plane polar GaN.

18. A method comprising:
providing a crystalline semiconductor material;
implanting a plurality of particles into an exposed face of the material to create a subsurface cleave region;
bonding the exposed face to a substrate;
applying energy to cleave the material along the cleave plane to leave a layer bonded to the substrate; and
processing the layer for incorporation into a micro-light emitting diode (LED) structure.

19. A method as in claim 18 wherein processing the layer comprises:
forming a plurality of discrete pixels separated by streets; and
transferring the plurality of discrete pixels en masse to a target substrate.

20. A method as in claim 18 wherein processing the layer comprises:
forming a plurality of discrete pixels separated by streets; and
selectively transferring fewer than the entire plurality of discrete pixels to a target substrate.
